(19) United States
(12) Patent Application Publication
(10) Pub. No.: US 2026/0136769 A1
(43) Pub. Date: May 14, 2026

(54) Display Device

(71) Applicant: LG Display Co., Ltd., Seoul (KR)

(72) Inventors: Yongmin Kim, Paju-si (KR); JungSun Baek, Paju-si (KR); Seongjoo Lee, Paju-si (KR); Yosup Sim, Paju-si (KR)

(21) Appl. No.: 19/312,679

(22) Filed: Aug. 28, 2025

(30) Foreign Application Priority Data
Nov. 13, 2024 (KR) 10-2024-0161243

(51) Int. Cl. H10K 59/122; H10K 59/131; H10K 59/38; H10K 77/10

(52) U.S. Cl. CPC H10K 59/122; H10K 59/131; H10K 59/38; H10K 77/111

(57) ABSTRACT

Disclosed are a display device and a display panel. The display device includes a structure where an insulating layer is disposed between a planarization layer and a pixel electrode and includes an opening overlapping with a portion of the pixel electrode, and a convex insulating layer is disposed between the planarization layer and the pixel electrode, overlaps with the opening of the insulating layer, and has an island shape, and thereby, is providing a wide viewing angle with uniform brightness.

### CROSS REFERENCE TO RELATED APPLICATION

This application claims priority and the benefit of Republic of Korea Patent Application No. 10-2024-0161243, filed on Nov. 13, 2024, which is hereby incorporated by reference in its entirety.

### TECHNICAL FIELD

The present disclosure relates to electronic devices, and more specifically, to a display panel including at least one bent or curved edge to provide a visually smooth appearance, and thereby, providing aesthetic satisfaction and causing immersion in the screen to be increased, and a display device including the same.

### DISCUSSION OF RELATED ART

In today's information society, display devices for presenting images or visual information to users are increasingly important. The need for such display devices has caused display technology to advance, and various types of display devices, such as a liquid crystal display (LCD) device, a plasma display device, a quantum-dot light emitting display device, an organic light emitting display (e.g., OLED) device, an inorganic light emitting display device, and the like, have been developed and widely used.

In particular, recently work has been progressing on developing flexible display devices capable of displaying images even when bent or folded like paper as next generation display devices. Flexible display devices may include unbreakable display devices having high durability by utilizing plastic thin film transistor substrates instead of glass, bendable display devices capable of being bent without breaking, rollable display devices, foldable display devices, and the like. These flexible display devices can provide advantages in space utilization, interior, and design, and can have various applications.

### SUMMARY

The inventor has realized that: in related art, a display device including a bending area may be designed to have a central portion with a flat shape, and one or more side portions allowing the display device to be bent and including one or more corners. In this design, when the display device is bent, the one or more side portions may be bent in a curved shape, and thereby, when a user looks at the display device in front thereof, a viewing angle at which the user can see an image presented by the display device may be out of acceptable quality. In this situation, the user can note a reduced luminance of the displayed image at the one or more side portions. Thus, the user may recognize a significant difference in luminance between the flat portion in the central portion and the bent portion in the one or more side portions. To address these issues, display devices according to the independent claims are provided. Further embodiments are described in the dependent claims. One or more aspects of the present disclosure may provide a display device including at least one bent or curved edge to provide a visually smooth appearance, and thereby, providing aesthetic satisfaction and causing immersion in the screen to be increased.

One or more embodiments of the present disclosure may provide a display device that has a structure in which a pixel electrode is disposed on a convex insulating layer, so that light emitted from a light emitting element is directed at various angles by a convex or curved portion of the convex insulating layer, and thereby, is capable of significantly increasing a viewing angle.

One or more embodiments of the present disclosure may provide a display device that has a structure in which a pixel electrode includes at least one inclined portion corresponding to the configuration of an insulating layer, so that light emitted from a light emitting element is directed to the outside without being totally reflected into the inside of a display panel, and thereby, is capable of improving luminance of the display panel.

One or more embodiments of the present disclosure may provide a display device that has a structure in which the display device includes a flat central area and at least one bent or curved edge area, and thereby, is capable of enabling a user to see an image or visual information without recognizing a difference in luminance between the flat central area and the at least one bent or curved edge area.

One or more embodiments of the present disclosure may provide a display device that has a structure in which the display device includes a bending area located in at least one edge thereof, and is configured to cause a viewing angle to gradually increase as a user moves away from a central area of a display panel in the bending area, and thereby, is capable of enabling the user to recognize uniform luminance in the bending area.

One or more embodiments of the present disclosure may provide a display device having a structure of causing light being totally reflected into the inside of a display panel to be directed to the outside, and providing high brightness with low power.

Issues or needs for solving in the present disclosure are not limited to the issues or needs described above, and other issues or needs will become apparent to those skilled in the art from the following description.

According to one or more example embodiments of the present disclosure, a display device can be provided that includes a substrate including a flat area and a bending area, a planarization layer disposed on the substrate, a first pixel electrode located in the flat area and disposed in a pixel electrode layer on the planarization layer, a second pixel electrode located in the bending area and disposed in the pixel electrode layer on the planarization layer, an insulating layer disposed between the planarization layer and the pixel electrode layer, and including a first opening overlapping with a portion of the first pixel electrode and a second opening overlapping with a portion of the second pixel electrode, at least one first convex insulating layer disposed on the planarization layer, located in an island shape in the first opening, and having a convex shape, and at least one second convex insulating layer disposed on the planarization layer, located in an island shape in the second opening, and having a convex shape. In one or more aspects, the first pixel electrode may include a first curved surface disposed along an upper surface of the at least one first convex insulating layer in the first opening, and the second pixel electrode may include a second curved surface disposed along an upper surface of the at least one second convex insulating layer in the second opening. In one or more aspects, an area of a lower surface of the at least one second convex insulating layer may be greater than that of a lower surface of the at least one first convex insulating layer.

According to one or more example embodiments of the present disclosure, a display device can be provided that includes a substrate on which a plurality of subpixels are disposed, a plurality of main light emitting areas overlapping with the plurality of subpixels, a plurality of sub-light emitting areas surrounding the plurality of main light emitting areas, wherein at least one diffuse light emitting area is included in each of the plurality of main light emitting areas. In one or more aspects, and the diffuse light emitting area may cause light emitted therefrom to have an emission angle that is not perpendicular to the substrate.

According to one or more example embodiments of the present disclosure, a display device can be provided that includes a substrate; a planarization layer disposed on the substrate; pixel electrodes disposed in a pixel electrode layer on the planarization layer; an insulating layer disposed between the planarization layer and the pixel electrode layer, and comprising openings overlapping with pixel electrodes; and at least one convex insulating layers disposed between the planarization layer and pixel electrodes, located in an island shape in the openings, and having a convex shape.

According to one or more example embodiments of the present disclosure, a display panel can be provided that includes a substrate including a flat area and a bending area, a planarization layer disposed on the substrate, a first pixel electrode located in the flat area and disposed in a pixel electrode layer on the planarization layer, a second pixel electrode located in the bending area and disposed in the pixel electrode layer on the planarization layer, an insulating layer disposed between the planarization layer and the pixel electrode layer, and including a first opening overlapping with a portion of the first pixel electrode and a second opening overlapping with a portion of the second pixel electrode, at least one first convex insulating layer disposed on the planarization layer, located in an island shape in the first opening, and having a convex shape, and at least one second convex insulating layer disposed on the planarization layer, located in an island shape in the second opening, and having a convex shape. In one or more aspects, the first pixel electrode may include a first curved surface disposed along an upper surface of the at least one first convex insulating layer in the first opening, and the second pixel electrode may include a second curved surface disposed along an upper surface of the at least one second convex insulating layer in the second opening. In one or more aspects, an area of a lower surface of the at least one second convex insulating layer may be greater than that of a lower surface of the at least one first convex insulating layer.

According to one or more example embodiments of the present disclosure, a display panel can be provided that includes a substrate on which a plurality of subpixels are disposed, a plurality of main light emitting areas overlapping with the plurality of subpixels, a plurality of sub-light emitting areas surrounding the plurality of main light emitting areas, wherein at least one diffuse light emitting area is included in each of the plurality of main light emitting areas. In one or more aspects, and the diffuse light emitting area may cause light emitted therefrom to have an emission angle that is not perpendicular to the substrate.

According to one or more example embodiments of the present disclosure, a display panel can be provided that includes a substrate; a planarization layer disposed on the substrate; pixel electrodes disposed in a pixel electrode layer on the planarization layer; an insulating layer disposed between the planarization layer and the pixel electrode layer, and comprising openings overlapping with pixel electrodes; and at least one convex insulating layers disposed between the planarization layer and pixel electrodes, located in an island shape in the openings, and having a convex shape.

According to one or more embodiments of the present disclosure, a display device may be provided that includes at least one curved edge to provide a visually smooth appearance, and thereby, provides aesthetic satisfaction and causes immersion in the screen to be increased.

According to one or more embodiments of the present disclosure, a display device may be provided that has a structure in which a pixel electrode is disposed on a convex insulating layer, so that light emitted from a light emitting element is directed at various angles by a convex or curved portion of the convex insulating layer, and thereby, is capable of significantly increasing a viewing angle.

According to one or more aspects of the present disclosure, a display device may be provided that has a structure in which a pixel electrode includes at least one inclined portion corresponding to the configuration of an insulating layer, so that light emitted from a light emitting element is directed to the outside without being totally reflected into the inside of a display panel, and thereby, is capable of improving luminance of the display panel.

According to one or more embodiments of the present disclosure, a display device may be provided that has a structure in which the display device includes a flat central area and at least one bent or curved edge area, and thereby, is capable of enabling a user to see an image or visual information without recognizing a difference in luminance between the flat central area and the at least one bent or curved edge area.

According to one or more embodiments of the present disclosure, a display device may be provided that has a structure in which the display device includes a bending area located in at least one edge thereof, and is configured to cause a viewing angle to gradually increase as a user moves away from a central area of a display panel in the bending area, and thereby, is capable of enabling the user to recognize uniform luminance in the bending area.

According to one or more embodiments of the present disclosure, a display device may be provided that has a structure of causing light being totally reflected into the inside of a display panel to be directed to the outside, and providing high brightness with low power.

Effects or advantages resulting from example embodiments described herein are not limited to the effects or advantages described above, and other effects or advantages will become apparent to those skilled in the art from the following description.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIG. 1 illustrates a system configuration of an example display device according to embodiments of the present disclosure;

FIG. 2 is a perspective view of an example display panel according to embodiments of the present disclosure;

FIG. 3 illustrates an example circuit of a subpixel included in the display device according to embodiments of the present disclosure;

FIG. 4 is an example cross-sectional view of area A in FIG. 2 according to embodiments of the present disclosure;

FIG. 5 is another example cross-sectional view of area A in FIG. 2 according to embodiments of the present disclosure;

FIG. 6 is an example plan view of area A in FIG. 2 according to embodiments of the present disclosure;

FIG. 7 illustrates respective example cross-sectional views of a flat area and a bending area in the display panel according to embodiments of the present disclosure;

FIG. 8 is an example plan view of the display panel according to embodiments of the present disclosure;

FIG. 9 is an example plan view of a zeroth pixel disposed in the flat area of the display panel in FIG. 8 according to embodiments of the present disclosure;

FIG. 10 is an example plan view of a first pixel disposed in a first bending area of the display panel in FIG. 8 according to embodiments of the present disclosure;

FIG. 11 is an example cross-sectional view taken along line X-X′ of the display panel in FIG. 8 according to embodiments of the present disclosure;

FIG. 12 is another example plan view of the first pixel disposed in the first bending area of the display panel in FIG. 8 according to embodiments of the present disclosure;

FIG. 13 is an example plan view of a second pixel disposed in a second bending area of the display panel in FIG. 8 according to embodiments of the present disclosure;

FIG. 14 is an example plan view of a sixth pixel disposed in a sixth bending area of the display panel in FIG. 8 according to embodiments of the present disclosure;

FIG. 15 is another example cross-sectional view taken along line X-X′ of the display panel in FIG. 8 according to embodiments of the present disclosure;

FIG. 16 is an example graph showing how luminance on a side or edge of the display panel relative to luminance in the vertical direction of the display panel is changed with respect to the diameter of a convex insulating layer according to embodiments of the present disclosure;

FIG. 17 is an example graph showing an amount of light emitted per current with respect to x values of green in the CIE color coordinates measured in the display panel in each case according to embodiments of the present disclosure;

FIG. 18 is an example graph showing luminance efficiency of the display panel at a 60° viewing angle in each case according to embodiments of the present disclosure;

FIG. 19 is a table showing example configurations of insulating layers and convex insulating layers respectively disposed in the flat area and the bending area according to embodiments of the present disclosure; and

FIG. 20 is a table showing the number and diameter of convex insulating layers disposed on a red subpixel, and a relevant fill factor according to embodiments of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “include,” “have,” “comprise,” “contain,” “constitute,” “make up of,” “formed of,” and “consist of” used herein are generally intended to allow other components to be added unless the terms are used with the term “only”. As used herein, singular forms are intended to include plural forms unless the context clearly indicates otherwise.

The shapes, sizes, dimensions (e.g., length, width, height, thickness, radius, diameter, area, etc.), ratios, angles, numbers of elements, and the like illustrated in the accompanying drawings for describing the exemplary embodiments of the present disclosure are merely examples, and the present disclosure is not limited thereto. Like reference numerals generally denote like elements throughout the specification.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The word “exemplary” is used to mean serving as an example or illustration. Aspects are example aspects. “Embodiments,” “examples,” “aspects,” and the like should not be construed as preferred or advantageous over other implementations. An embodiment, an example, an exemplary embodiment, an aspect, or the like may refer to one or more embodiments, one or more examples, one or more example embodiments, one or more aspects, or the like, unless stated otherwise. Further, the term “may” encompasses all the meanings of the term “can.”

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

Where positional relationships are described, for example, where the positional relationship between two parts is described using “on”, “above”, “over”, “below”, “under”, “beside”, “beneath”, “near”, “close to,” “adjacent to”, “on a side of”, “next” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the exemplary term “below” can encompass both an orientation of below and above. Similarly, the exemplary term “above” or “over” can encompass both an orientation of “above” and “below”.

When a temporal relationship is described, for example, when terms for temporal relationship of events such as “after”, “subsequently”, “next”, and “before” are used, there may also be the case in which the events are not continuous, unless “immediately” or “directly” is used.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

The term “at least one” should be understood as including all possible combinations which can be suggested from one or more relevant items. For example, the meaning of “at least one of a first item, a second item, or a third item” may be each one of the first item, the second item, or the third item and also be all possible combinations that can be suggested from two or more of the first item, the second item, and the third item.

A term “device” used herein may refer to a display device including a display panel and a driver for driving the display panel. Examples of the display device may include a light emitting element, and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

The features of various embodiments of the present disclosure can be partially or entirely adhered to or combined with each other and can be interlocked and operated in technically various ways, and the embodiments can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

In the specification, in adding reference numerals for elements in each drawing, it should be noted that like reference numerals already used to denote like elements in other drawings are used for elements wherever possible. In addition, the dimension scales of constituent elements shown in the drawings may be different from actual dimension scales, for convenience of description. That is, the dimension scales of constituent elements shown in the drawings should not be interpreted to be the same as those shown in the drawings.

Hereinafter, with reference to the accompanying drawings, various example embodiments of the present disclosure will be described in detail.

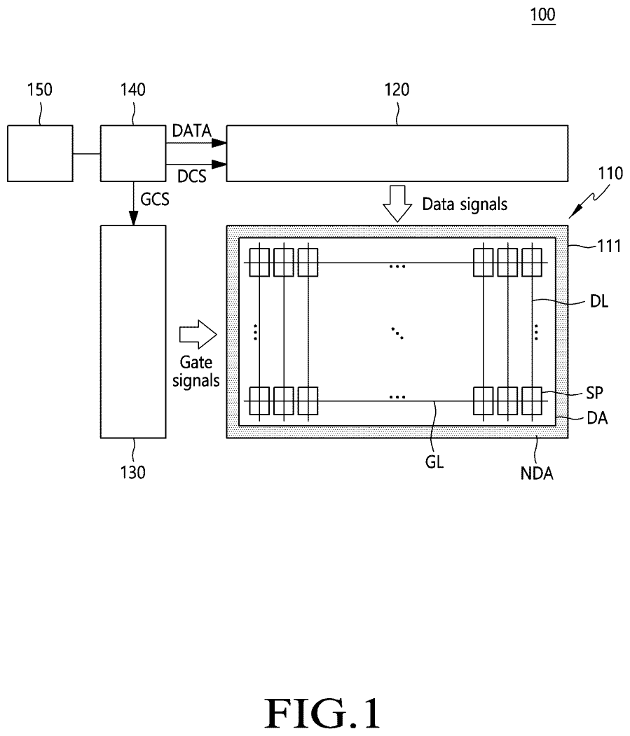

FIG. 1 illustrates an example system configuration of a display device 100 according to aspects of the present disclosure.

Referring to FIG. 1, in one or more example embodiments, the display device 100 may include a display panel 110 and a display driving circuit, as elements for display images. The display driving circuit may be a circuit for driving the display panel 110, and include a data driving circuit 120, a gate driving circuit 130, a touch sensing circuit (not shown in the drawings), a display controller 140, and other circuit components.

The display panel 110 may include a substrate 111 and a plurality of subpixels SP disposed on the substrate 111.

The substrate 111 may be formed of an insulating material or a material with flexibility, but is not limited thereto. For example, the substrate may include a flexible polymer film. For example, the flexible polymer film may be made of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), and polystyrene (PS). For example, the substrate may include a transparent polyimide material, and the present disclosure is not limited thereto.

The substrate 111 of the display panel 110 may include a display area DA allowing an image to be displayed and a non-display area NDA located outside of the display area DA. The non-display area NDA may be an area where no image is displayed and may be defined in an edge portion of the display panel to surround a portion or the entirety of the display area DA. The non-display area NDA may be an area adjacent to the display area DA. Further, the non-display area NDA may be an area disposed adjacent to the display area DA and configured to surround the display area DA. However, the present disclosure is not limited thereto.

The display area DA may also be referred to as an active area, and a plurality of subpixels SP for displaying images may be disposed in the display area DA. The non-display area NDA may also be referred to as a non-active area and may include a pad area PA.

In one or more embodiments, the non-display area NDA of the display panel 110 may have a very small area compared to the display area DA. Herein, the non-display area NDA may be also referred to as a “bezel” or a “bezel area.” For example, the non-display area NDA may include a first non-display area located outside of the display area DA in a first direction, a second non-display area located outside of the display area DA in a second direction, a third non-display area located outside of the display area DA in a direction opposite to the first direction, and a fourth non-display area located outside of the display area DA in a direction opposite to the second direction.

The first non-display area among the first to fourth non-display areas may include a pad area to which one or more driving circuits are connected or bonded. Among the first to fourth non-display areas, the second to fourth non-display areas may have a very small size compared to the first non-display area.

In one or more embodiments, a boundary area between the display area DA and the non-display area NDA may be bent, and thereby, the non-display area NDA may be located under the display area DA. In this implementation, when a user looks at the display device 100 in front thereof, all or most of the non-display area NDA may not be visible to the user. For example, the first non-display area may include a bending area. As the bending area is bent, the first non-display area may not be visible in front of the display device 100.

Various types of signal lines for driving a plurality of subpixels SP may be disposed on the substrate 111 of the display panel 110.

In one or more embodiments, the display device 100 may be a liquid crystal display device, a self-emission display device in which light is emitted from the display panel 110 itself, or the like. In an example where the display device 100 is a self-emission display device, each of the plurality of subpixels SP included in the display device 100 may include a light emitting element such as an organic light emitting diode, an inorganic light emitting diode, a quantum dot light emitting diode, a micro light emitting diode, a mini light emitting diode, or the like.

Each of the plurality of subpixels SP may emit light having different wavelengths from each other. For example, the plurality of subpixels SP may include red, green, and blue subpixels, in which the red, green, and blue subpixels may be disposed in a repeated manner. Alternatively, the plurality of subpixels SP may include red, green, blue, and white subpixels, in which the red, green, blue, and white subpixels may be disposed in a repeated manner, or the red, green, blue, and white subpixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the embodiment of the present disclosure, the color type, disposition type, and disposition order of the subpixels are not limiting, and may be configured in various forms according to light-emitting characteristics, device lifespans, and device specifications.

Meanwhile, the subpixels may have different light-emitting areas according to light-emitting characteristics. For example, a subpixel that emits light of a color different from that of a blue subpixel may have a different light-emitting area from that of the blue subpixel. For example, the red subpixel, the blue subpixel, and the green subpixel, or the red subpixel, the blue subpixel, the white subpixel, and the green subpixel may each have a different light-emitting area.

In one or more aspects, the display device 100 may be an organic light emitting display device in which the light emitting element is implemented using an organic light emitting diode (OLED). In one or more embodiments, the display device 100 may be an inorganic light emitting display device in which the light emitting element is implemented using an inorganic material-based light emitting diode. In one or more aspects, the display device 100 may be a quantum dot display device in which the light emitting element is implemented using quantum dots, which are self-emission semiconductor crystals.

The structure of each of the plurality of subpixels SP may depend on types of display device 100. For example, when the display device 100 is a self-emission display device including self-emission subpixels SP, each subpixel SP may include a self-emission light emitting element, one or more transistors, and one or more capacitors.

The one or more transistors may be thin film transistors TFTs, and the active layer of the thin film transistors TFTs may be formed of a semiconductor material such as an oxide semiconductor, amorphous silicon, or polysilicon, but is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto.

The amorphous semiconductor material may be made of amorphous silicon (a-Si), but is not limited thereto.

The various types of signal lines disposed on the substrate 111 may include, for example, a plurality of data lines DL for carrying data signals (which may be referred to as data voltages or image signals), a plurality of gate lines GL for carrying gate signals (which may be referred to as scan signals), and the like.

In one or more embodiments, the plurality of data lines DL and the plurality of gate lines GL may intersect one another. Each of the plurality of data lines DL may be configured to extend in a first direction, and each of the plurality of gate lines GL may be configured to extend in a second direction. For example, the first direction may be the column direction, and the second direction may be the row direction. In another example, the first direction may be the row direction, and the second direction may be the column direction. Hereinafter, for merely convenience of explanation, discussions may be provided based on examples where the first direction is the column direction and the second direction is the row direction. In addition, for convenience of explanation, discussions may be provided based on examples where each of a plurality of data lines DL is disposed in the column direction, and each of a plurality of gate lines GL is disposed in the row direction. However, aspects of the present disclosure are not limited thereto.

The data driving circuit 120 may be a circuit for driving a plurality of data lines DL and can output data signals to the plurality of data lines DL.

The data driving circuit 120 can receive image data DATA in a digital form from the controller 140, and convert the received image data DATA into data signals in an analog form, and output converted data signals to the plurality of data lines DL.

In one or more embodiments, the data driving circuit 120 may be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique. However, aspects of the present disclosure are not limited thereto.

The data driving circuit 120 may be disposed in, and/or electrically connected to, but not limited to, only one side or edge (e.g., an upper portion or a lower portion) of the display panel 110. In one or more aspects, the data driving circuit 120 may be disposed in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The data driving circuit 120 may be connected to the outside, located outside, or located at a periphery, of the display area DA of the display panel 110, or be disposed in the display area DA of the display panel 110.

The gate driving circuit 130 may be a circuit for driving a plurality of gate lines GL and can output gate signals to the plurality of gate lines GL.

The gate driving circuit 130 can receive various types of gate driving control signals GCS, and further receive a first gate voltage corresponding to a turn-on level voltage and a second gate voltage corresponding to a turn-off level voltage. Thereby, the gate driving circuit 130 can generate gate signals and supply the generated gate signals to the plurality of gate lines GL.

In one or more embodiments, the gate driving circuit 130 included in the display device 100 may be embedded into the display panel 110 by a gate-in-panel (GIP) technique. However, embodiments of the present disclosure are not limited thereto. In an example where the gate driving circuit 130 is implemented by the gate-in-panel (GIP) technique, the gate driving circuit 130 may be disposed on the substrate 111 of the display panel 110 during the manufacturing process of the display panel 110 or display device 100.

For example, the gate driving circuit 130 may be disposed in the non-display area NDA of the display panel 110.

In one or more embodiments, the gate driving circuit 130 may be disposed in the display area DA of the display panel 110. In this implementation, for example, the gate driving circuit 130 may be disposed in, and/or electrically connected to, but not limited to, a first area (e.g., a left area or a right area) of the display area DA of the display panel 110. In another example, the gate driving circuit 130 may be disposed in, and/or electrically connected to, but not limited to, a first area (e.g., a left area or a right area) and a second area (e.g., the right area or the left area) of the display area DA of the display panel 110.

Herein, the gate driving circuit 130 embedded in the display panel 110 by the gate-in-panel (GIP) technique may also be referred to as a “gate-in-panel circuit.”

The touch sensing circuit might be connected via routing lines to a plurality of touch sensing lines. The touch sensing circuit may be a circuit for driving the plurality of touch sensing lines and can output touch sensing signals to the plurality of touch sensing lines.

The controller 140 may be a device configured to control the data driving circuit 120 and the gate driving circuit 130, and can control driving timing for the plurality of data lines DL and driving timing for the plurality of gate lines GL.

The controller 140 can supply a data control signal DCS to the data driving circuit 120 to control the data driving circuit 120, and supply a gate control signal GCS to the gate driving circuit 130 to control the gate driving circuit 130.

The controller 140 can receive image data input from a host system 150 and supply image data DATA readable by the data driving circuit 120 based on the input image data to the data driving circuit 120.

The controller 140 may be configured to be coupled with various processors, for example, a microprocessor, a mobile processor, an application processor, etc. in accordance with a device mounted therein.

The controller 140 may be implemented in a separate component from the data driving circuit 120, or integrated with the data driving circuit 120, so that the controller 140 and the data driving circuit 120 can be implemented in a single integrated circuit.

The controller 140 may be a timing controller used in the typical display technology or a control apparatus/device capable of additionally performing other control functionalities in addition to the typical function of the timing controller. In one or more embodiments, the controller 140 may be one or more other control circuits different from the timing controller, or a circuit or component in the control apparatus/device. The controller 140 may be implemented using various circuits or electronic components such as an integrated circuit (IC), a field programmable gate array (FPGA), an application specific integrated circuit (ASIC), a processor, and/or the like. However, aspects of the present disclosure are not limited thereto.

The controller 140 may be mounted on a printed circuit board, a flexible printed circuit, or the like, and may be electrically connected to the data driving circuit 120 and the gate driving circuit 130 through the printed circuit board, the flexible printed circuit, and/or the like.

The controller 140 can transmit signals to, and receive signals from, the data driving circuit 120 via one or more predetermined interfaces. For example, such interfaces may include a low voltage differential signaling (LVDS) interface, an embedded clock point-point interface (EPI), a serial peripheral interface (SPI), and the like. However, aspects of the present disclosure are not limited thereto.

The display device 100 may further include a power supply circuit for supplying various types of power to the display driving circuit and/or the touch sensing circuit.

In one or more embodiments, the display device 100 may be a mobile terminal such as a smart phone, a tablet, or the like, or a monitor, a television (TV), or the like. Such apparatuses may be configured in various types, sizes, and shapes. The display device 100 according to aspects of the present disclosure are not limited thereto, and may include various types, sizes, and shapes configured to display information or images. a display apparatus according to the aspects of the present disclosure may be applied to mobile devices, video phones, smart watches, watch phones, wearable apparatuses, foldable apparatuses, rollable apparatuses, bendable apparatuses, flexible apparatuses, stretchable apparatuses, curved apparatuses, sliding apparatuses, variable apparatuses, electronic notebooks, e-books, portable multimedia players (PMP), personal digital assistants (PDA), MP3 players, mobile medical apparatuses, desktop PCs, laptop PCs, netbook computers, workstations, navigation apparatuses, car navigation apparatuses, vehicle display apparatuses, vehicle apparatuses, theater apparatuses, theater display apparatuses, televisions, wallpaper apparatuses, signage apparatuses, game apparatuses, notebook computers, monitors, cameras, camcorders, and home appliances, and the like.

In one or more aspects, the display panel 110 may have four edges, and each of the four edges may have a curved or bent surface.

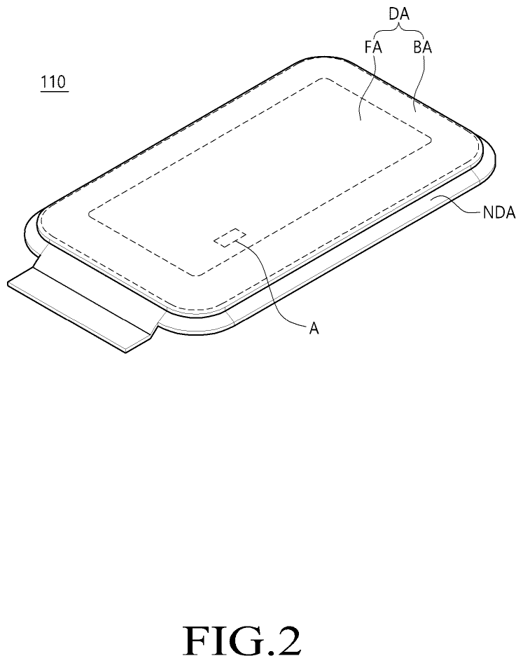

FIG. 2 is an example perspective view of the display panel 110 according to embodiments of the present disclosure.

Referring to FIG. 2, in one or more example embodiments, the display panel 110 may have four sides (or edges), and each of the four sides (or edges) may have a curved or bent surface. The sides (or edges) with curved surfaces may be referred to as bent (or curved) sides (or edges).

Referring to FIG. 2, the display panel 110 may have a flat area FA and a bending area BA, and the bending area BA may be formed such that a predefined curvature is applied from edges of the flat area FA of the display panel 110 to the bending area BA. The curvature may extend to the non-display area NDA, but embodiments of the present disclosure are not limited thereto. The bending area BA may be formed by bending edge areas of the display panel 110 with physical force.

As discussed above, the display area DA may include the flat area FA and the bending area BA to which the curvature is applied from the flat area FA to edges of the display panel 110.

As the display panel 110 includes curved (or bent) four sides (or edges), the display panel 110 can provide advantages of improving durability and improving resistance to external impact.

Further, curved edges of the bending area BA can provide a visually smooth appearance, thereby providing aesthetic satisfaction to a user. Further, as edges or sides of the display panel 110 are bent, the display panel 110 can provide advantages or effects of alleviating the sense of separation between the flat area FA and the bending area BA and causing immersion in the screen to be increased.

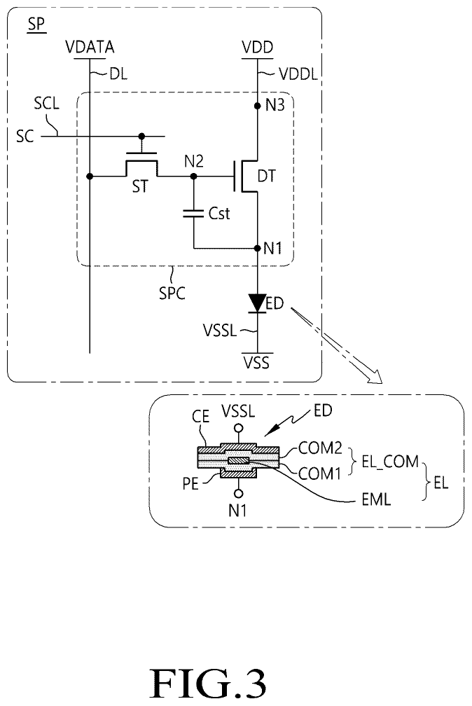

FIG. 3 illustrates an example circuit of a subpixel SP included in the display device 100 according to embodiments of the present disclosure.

Referring to FIG. 3, in an example where the display device 100 is a self-emission display device, each of a plurality of subpixels SP disposed on the substrate 111 may include a light emitting element ED and a subpixel circuit SPC for driving the light emitting element ED.

Referring to FIG. 3, the subpixel circuit SPC may include a plurality of transistors and at least one capacitor for driving the light emitting element ED, but embodiments of the present disclosure are not limited to such specific structures. The subpixel circuit SPC can drive the light emitting element ED by supplying a driving current to the light emitting element ED at a predetermined timing. The light emitting element ED can emit light by being driven by the driving current.

The plurality of transistors may include a driving transistor DT for driving the light emitting element ED and a scan transistor ST configured to be turned on or off by a scan signal SC.

The driving transistor DT can supply a driving current to the light emitting element ED.

The scan transistor ST may be configured to control an electrical state of a corresponding node in the subpixel circuit SPC or to control the state or operation of the driving transistor DT.

The at least one capacitor may include a storage capacitor Cst configured to maintain a constant voltage during a display frame or a certain period of the display frame.

To drive at least one subpixel SP, at least one data signal VDATA, which is an image signal, and at least one scan signal SC, which is a gate signal, may be applied to the subpixel SP. Further, a common pixel driving voltage including a first common driving voltage VDD and a second common driving voltage VSS may be applied to the subpixel SP.

The light emitting element ED may include a pixel electrode PE, an intermediate layer EL, and a common electrode CE. The intermediate layer EL may be disposed between the pixel electrode PE and the common electrode CE.

For example, the pixel electrode PE may be an electrode disposed in each subpixel SP, and the common electrode CE may be an electrode commonly disposed in all or some of a plurality of subpixels SP. For example, the pixel electrode PE may be an anode electrode, and the common electrode CE may be a cathode electrode. In another example, the pixel electrode PE may be a cathode electrode, and the common electrode CE may be an anode electrode. Hereinafter, for convenience of explanation, discussions may be provided based on examples where the pixel electrode PE is an anode electrode, and the common electrode CE is a cathode electrode.

In an example where the light emitting element ED is an organic light emitting diode, the intermediate layer EL may include an emission layer EML, a first common intermediate layer COM1 between the pixel electrode PE and the emission layer EML, and a second common intermediate layer COM2 between the emission layer EML and the common electrode CE. A layer including the first common intermediate layer COM1 and the second common intermediate layer COM2 may be referred to as a common intermediate layer EL_COM. Even though in FIG. 3 only one emission layer EML is shown, the application is not limited thereto. For example, a tandem structure including a plurality of emission layers EML can be employed.

The emission layer EML may be disposed in each subpixel SP, and the common intermediate layer EL_COM may be commonly disposed across a plurality of subpixels SP.

The emission layer EML may be disposed in each light emitting area, and the common intermediate layer EL_COM may be commonly disposed across a plurality of light emitting areas and a plurality of non-light emitting areas.

For example, the first common intermediate layer COM1 may include a hole injection layer (HIL), an electron blocking layer (EBL), a hole transfer layer (HTL), and/or the like, but aspects of the present disclosure are not limited thereto. The second common intermediate layer COM2 may include an electron transport layer (ETL), a hole blocking layer (HBL), an electron injection layer (EIL), and/or the like, but aspects of the present disclosure are not limited thereto.

The hole injection layer can inject holes from the pixel electrode PE to the hole transport layer, the hole transport layer can transport holes to the emission layer EML, the electron injection layer can inject electrons from the common electrode CE to the electron transport layer, and the electron transport layer can transport electrons to the emission layer EML.

For example, the common electrode CE may be electrically connected to a second common driving voltage line VSSL (which may be also referred to as a base voltage line VSSL). The second common driving voltage VSS may be applied to the common electrode CE through the second common driving voltage line VSSL. The pixel electrode PE may be electrically connected directly or indirectly (via another transistor) to a first node N1 of the corresponding driving transistor DT of each subpixel SP. Herein, the second common driving voltage VSS may also be referred to as a base voltage, a low voltage, or a low power supply voltage, and the second common driving voltage line VSSL may also be referred to as a base voltage line, a low voltage line, or a low power supply voltage line.

Each light emitting element ED may be configured by the overlap of the pixel electrode PE, the emission layer EML in the intermediate layer EL, and the common electrode CE. A corresponding light emitting area may be formed by each light emitting element ED. For example, a corresponding light emitting area of each light emitting element ED may include an area at which the pixel electrode PE, the emission layer EML in the intermediate layer EL, and the common electrode CE overlap with each other.

In one or more embodiments, the light emitting element ED may be an organic light emitting diode (OLED), an inorganic light emitting diode (LED), a quantum dot (QD) light emitting element, a micro light emitting diode, a mini light emitting diode, or the like, but aspects of the present disclosure are not limited thereto. For example, in an example where the light emitting element ED is an organic light emitting diode OLED, the intermediate layer EL of the light emitting element ED may be a layer including an organic material.

Referring to FIG. 2, the driving transistor DT may be a transistor configured to supply a driving current to the light emitting element ED. The driving transistor DT may be connected between a first common driving voltage line VDDL and the light emitting element ED.

The driving transistor DT may include a first node N1, a second node N2, and a third node N3. The first node N1 may be electrically connected to the light emitting element ED. A data signal VDATA may be applied to the second node N2. The first common driving voltage VDD transmitted through the first common driving voltage line VDDL may be applied to the third node N3.

The second node N2 may be, or correspond to, a gate node of the driving transistor DT, the first node N1 may be, or correspond to, a source node or a drain node of the driving transistor DT, and the third node N3 may be, or correspond to, the drain node or the source node of the driving transistor DT. Hereinafter, for merely convenience of explanation, discussions may be provided based on examples where the first, second, and third nodes (N1, N2, and N3) of the driving transistor DT are source, gate, and drain nodes, respectively. However, aspects of the present disclosure are not limited thereto.

The scan transistor ST included in the subpixel circuit SPC illustrated in FIG. 3 may be a switching transistor for allowing a data signal VDATA, which is an image signal, to be supplied to the second node N2, which is the gate node of the driving transistor DT.

The scan transistor ST can be turned on or turned off by a scan signal SC, which is a type of gate signal, applied through a scan line SCL, which is a type of gate line GL, and control an electrical connection between the second node N2 of the driving transistor DT and a data line DL. The drain electrode or source electrode of the scan transistor ST may be electrically connected to the data line DL. The source electrode or drain electrode of the scan transistor ST may be electrically connected to the second node N2 of the driving transistor DT. The gate electrode of the scan transistor ST may be electrically connected to the scan line SCL.

The storage capacitor Cst may be electrically connected between the first node N1 and the second node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst may be an external capacitor intentionally designed to be located or disposed outside of the driving transistor DT, and therefore, be different from an internal capacitor such as a parasitic capacitor (e.g., a Cgs, a Cgd, or the like) that may be formed between the first node N1 and the second node N2 of the driving transistor DT. However, aspects of the present disclosure are not limited thereto.

Each of the driving transistor DT and the scan transistor ST may be an n-type transistor or a p-type transistor.

The display panel 110 may have a top emission structure or a bottom emission structure.

In an example where the display panel 110 has the top emission structure, at least a portion of the subpixel circuit SPC may overlap with at least a portion of the light emitting element ED in the vertical direction. In this configuration, the area or size of the corresponding light emitting area can increase, and as a result, a corresponding aperture ratio can increase.

In an example where the display panel 110 has the bottom emission structure, the subpixel circuit SPC may not overlap with the light emitting element ED in the vertical direction.

As shown in FIG. 3, the subpixel circuit SPC may include two transistors (2T: DT and ST) and one capacitor (1C: Cst) (which may be referred to as a “2T1C structure”), and in some implementations, may further include one or more transistors, or further include one or more capacitors.

For example, the subpixel circuit SPC may have an 8T1C structure including 8 transistors and 1 capacitor. In another example, the subpixel circuit SPC may have a 6T2C structure including 6 transistors and 2 capacitor. In another example, the subpixel circuit SPC may have a 7T1C structure including 7 transistors and 1 capacitor. However, example embodiments of the present disclosure are not limited to such specific structures.

The types and number of gate signals supplied to a subpixel SP, and/or the types and number of gate lines connected to the subpixel SP may vary depending on a structure of a corresponding subpixel circuit SPC. Further, the types and number of common pixel driving voltages supplied to a subpixel SP may vary depending on a structure of a corresponding subpixel circuit SPC.

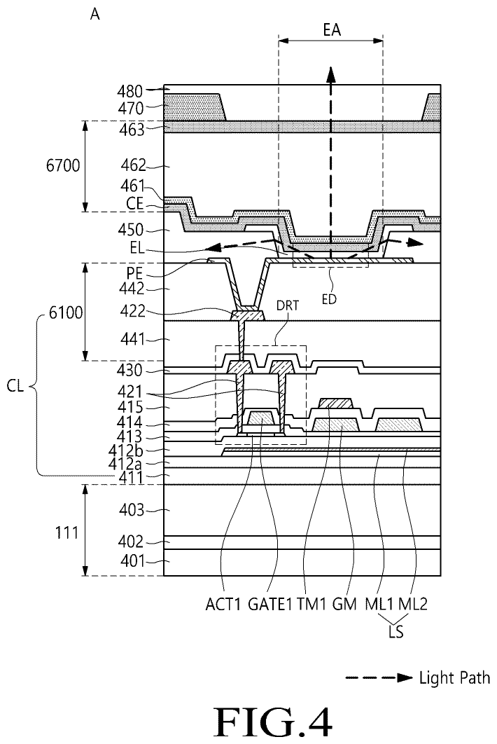

FIG. 4 is an example cross-sectional view of area A in FIG. 2 according to one embodiment.

Area A shown in FIG. 2 may be an area of the display area DA including one subpixel SP and a light emitting area EA.

A stackup configuration of the display panel 110 will be described with reference to FIG. 4.

Referring to FIG. 4, the substrate 111 may include a first substrate 401, an interlayer insulating layer 402, and a second substrate 403. The interlayer insulating layer 402 may be located between the first substrate 401 and the second substrate 403. As the substrate 111 includes the first substrate 401, the interlayer insulating layer 402, and the second substrate 403, the display panel 110 can provide an advantage of preventing the penetration of moisture. For example, the first substrate 401 and the second substrate 403 may be polyimide (PI) substrates. The first substrate 401 may be referred to as a primary PI substrate, and the second substrate 403 may be referred to as a secondary PI substrate.

Referring to FIG. 4, various types of patterns (ACT1, SD1, GATE1) for forming one or more transistors such as a driving transistor DRT, and the like, various types of insulating layers (411, 412a, 412b, 413, 414, 415, 430), and various types of metal patterns (TM1, GM, ML1, ML2) may be disposed on the substrate SUB.

Referring to FIG. 4, a multi-buffer layer 411 may be disposed on the second substrate 403, and a first active buffer layer 412a may be disposed on the multi-buffer layer 411. For example, the first active buffer layer 412a may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the exemplary embodiments of the present disclosure are not limited thereto. The first active buffer layer 412a may be excluded in accordance with the structure or properties of the display device.

A first metal layer ML1 and a second metal layer ML2 may be disposed on the first active buffer layer 412a. In one or more aspects, the first metal layer ML1 and the second metal layer ML2 may be light shield layers LS serving to shield light.

A second active buffer layer 412b may be disposed on the first metal layer ML1 and the second metal layer ML2. For example, the second active buffer layer 412b may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the exemplary embodiments of the present disclosure are not limited thereto. A first active layer ACT1 of a driving transistor DRT may be disposed on the second active buffer layer 412b.

A first gate insulating layer 413 may be disposed such that the first gate insulating layer 413 covers the first active layer ACT1. For example, the first gate insulating layer 413 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the exemplary embodiments of the present disclosure are not limited thereto.

A first gate electrode GATE1 of the driving transistor DRT may be disposed on the first gate insulating layer 413. In one or more aspects, in addition to the first gate electrode GATE1 of the driving transistor DRT, at least one gate material layer GM may be disposed on the first gate insulating layer 413 at a location different from a location at which the driving transistor DRT is disposed.

A first interlayer insulating layer 414 may be disposed on the first gate electrode GATE1 and the gate material layer GM such that the first interlayer insulating layer 414 covers the first gate electrode GATE1 and the gate material layer GM. For example, the first interlayer insulating layer 414 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the exemplary embodiments of the present disclosure are not limited thereto. A metal pattern TM1 may be disposed on the first interlayer insulating layer 414. The metal pattern TM1 may be located at a location different from the location where the driving transistor DRT is disposed. A second interlayer insulating layer 415 may be disposed on the metal pattern TM1 on the first interlayer insulating layer 414 such that the second interlayer insulating layer 415 covers the metal pattern TM1. For example, the second interlayer insulating layer 415 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the exemplary embodiments of the present disclosure are not limited thereto.

Two first source-drain electrode patterns 421 may be disposed on the second interlayer insulating layer 415. One of the two first source-drain electrode patterns 421 may be a source node of the driving transistor DRT, and the other thereof may be a drain node of the driving transistor DRT. The two first source-drain electrode patterns 421 may be electrically connected to first and second side portions of the first active layer ACT1, respectively, through contact holes of the second interlayer insulating layer 415, the first interlayer insulating layer 414, and the first gate insulating layer 413.

A portion of the first active layer ACT1 overlapping with the first gate electrode GATE1 may be referred to as a channel region. One of the two first source-drain electrode patterns 421 may be connected to the first side portion of the channel region of the first active layer ACT1, and the other of the two first source-drain electrode patterns 421 may be connected to the second side portion of the channel region of the first active layer ACT1.

A passivation layer 430 may be disposed on the two first source-drain electrode patterns 421 such that the passivation layer 430 covers the two first source-drain electrode patterns 421. A planarization layer 440 (not shown) may be disposed on the passivation layer 430. The planarization layer 440 may include a first planarization layer 441 and a second planarization layer 442.

For example, the first planarization layer 441 may be disposed on the passivation layer 430. For example, the first planarization layer 441 may include an organic insulating material, and the organic insulating material may include acrylic resin or photosensitive polyimide, but not limited thereto.

A second source-drain electrode pattern 422 may be disposed on the first planarization layer 441. The second source-drain electrode pattern 422 may be connected to one of the two first source-drain electrode patterns 421 (corresponding to the second node N2 of the driving transistor DRT in the subpixel SP of FIG. 3) through a contact hole of the first planarization layer 441.

The second planarization layer 442 may be disposed on the second source-drain electrode pattern 422 such that the second planarization layer 442 covers the second source-drain electrode pattern 422. For example, the second planarization layer 442 may include an organic insulating material, and the organic insulating material may include acrylic resin or photosensitive polyimide, but not limited thereto. The configuration from the multi-buffer layer 411 to the second planarization layer 442 may be collectively referred to as a circuit layer CL, wherein the configuration from the first planarization layer 441 to the second planarization layer 442 may be referred to as a circuit connection area 6100. In addition, the configuration from cathode electrode CE to the third encapsulation layer 463 may be referred to as a common area 6700, but not limited thereto.

A light emitting element ED of a subpixel SP may be disposed on the second planarization layer 442.

In an example stack-up configuration of the light emitting element ED, an anode electrode PE may be disposed on the second planarization layer 442. The anode electrode PE of FIG. 4 may represent the pixel electrode PE of FIG. 3. The anode electrode PE may be electrically connected to the second source-drain electrode pattern 422 through a contact hole of the second planarization layer 442.

A bank 450 may be disposed on the anode electrode PE such that the bank 450 covers a portion of the anode electrode PE. A portion of the bank 450 corresponding to the light emitting area EA of the subpixel SP may be opened.

According to the present disclosure, the bank 450 may be disposed in each of the plurality of sub-pixels. The bank 450 may be formed of an opaque material (for example, black) in order to prevent light interference between adjacent pixels. In this case, the bank 450 may include a light shielding material constituted by at least one of a color pigment, organic black, or carbon, without being limited thereto.

For example, the bank 450 may include an inorganic insulating material, such as silicon nitride (SiNx) or silicon oxide (SiOx), or the bank 450 may be formed of black resin. Meanwhile, the bank 450 can be formed of an organic layer such as an acryl-based material, an epoxy-based material, a phenolic-based material, a polyamide-based material, or a polyimide-based material. However, the present disclosure is not limited thereto.

A portion of the anode electrode PE may be exposed through the opening (the opened portion) of the bank 450. An emission layer EL may be disposed on one or more side surfaces of the bank 450 and in the opening (the opened portion) of the bank 450. All or at least part of the emission layer EL may be located between adjacent banks 450. The emission layer EL of FIG. 4 may represent the emission layer EML of FIG. 3.

In the opening of the bank 450, the emission layer EL may contact the anode electrode PE. A cathode electrode CE may be disposed on the emission layer EL. The cathode electrode CE of FIG. 4 may represent the common electrode CE of FIG. 3.

The light emitting element ED can be formed by including the anode electrode PE, the emission layer EL, and the cathode electrode CE. The emission layer EL may include an organic material layer.

Referring to FIG. 4, since circuit elements (e.g., light emitting elements ED such as organic light emitting diodes (OLED) including an organic material) in each subpixel SP may be easily damaged by external moisture or oxygen, an encapsulation layer 460 (not shown) may be disposed in the display panel 110 to prevent external moisture or oxygen from penetrating into the circuit elements (e.g., the light emitting elements ED).

The encapsulation layer 460 may be disposed in various shapes or configurations to prevent light emitting elements ED from contacting moisture or oxygen. For example, the encapsulation layer 460 may include two or more layers in which one or more organic layers and one or more inorganic layers are alternately stacked, but aspects of the present disclosure are not limited thereto. The encapsulation layer 460 may have a single layer stack or a multilayer stack. For example, the encapsulation layer may include a first inorganic encapsulation layer, a first organic encapsulation layer, and a second inorganic encapsulation layer, Alternatively, the encapsulation layer may include a first inorganic encapsulation layer, a first organic encapsulation layer, a second inorganic encapsulation layer, a second organic encapsulation layer, and a third inorganic encapsulation layer stacked sequentially.

The first inorganic encapsulation layer, the second inorganic encapsulation layer, and the third inorganic encapsulation layer may serve to block the penetration of moisture or oxygen. The first inorganic encapsulation layer, the second inorganic encapsulation layer, and the third inorganic encapsulation layer may be made of an inorganic material, for example, an inorganic material such as silicon nitride (SiNx), silicon oxide (SiOx), or aluminum oxide (AlOx). However, the present disclosure is not limited thereto.

The first organic encapsulation layer is disposed between the first inorganic encapsulation layer and the second inorganic encapsulation layer, and the second organic encapsulation layer is disposed between the second inorganic encapsulation layer and the third inorganic encapsulation layer. The first organic encapsulation layer and the second organic encapsulation layer may each have a larger thickness than each of the first inorganic encapsulation layer, the second inorganic encapsulation layer, and the third inorganic encapsulation layer in order to adsorb or block particles that may be produced during a process of manufacturing the display device. The first organic encapsulation layer and the second organic encapsulation layer may fill cracks that may be formed in the first inorganic encapsulation layer and the second inorganic encapsulation layer. The first organic encapsulation layer and the second organic encapsulation layer may planarize an upper portion of the first inorganic encapsulation layer and an upper portion of the second inorganic encapsulation layer by covering particles on the first inorganic encapsulation layer and the second inorganic encapsulation layer respectively. For example, the first organic encapsulation layer may planarize an upper portion of the first inorganic encapsulation layer by covering particles on the first inorganic encapsulation layer. For example, the second organic encapsulation layer may planarize an upper portion of the second inorganic encapsulation layer by covering particles on the second inorganic encapsulation layer. The first organic encapsulation layer and the second organic encapsulation layer may be made of an organic material, and for example, epoxy polymer, acrylic polymer, or the like may be used. However, the present disclosure is not limited thereto.

Meanwhile, the encapsulation layer is not limited to three or five layers, for example, n layers alternately stacked between inorganic encapsulation layer and organic encapsulation layer (where n is an integer greater than 3) may be included.

In one or more embodiments, as shown in FIG. 4, the encapsulation layer 460 may include a first encapsulation layer 461, a second encapsulation layer 462, and a third encapsulation layer 463.

For example, the first encapsulation layer 461 and the third encapsulation layer 463 may be inorganic layers, and the second encapsulation layer 462 may be an organic layer. Among the first encapsulation layer 461, the second encapsulation layer 462, and the third encapsulation layer 463, the second encapsulation layer 462 may be the thickest and serve as a planarization layer.

The first encapsulation layer 461 may be disposed on the cathode electrode CE. The first encapsulation layer 461 may include an inorganic insulating material capable of being deposited by low-temperature deposition. For example, the first encapsulation layer 461 may include, but not limited to, silicon nitride (SiNx), silicon oxide (SiOx), silicon oxynitride (SiON), aluminum oxide (Al2O3), or the like. Since the first encapsulation layer 461 is deposited in a low temperature atmosphere, during the deposition process, the first encapsulation layer 461 can prevent the emission layer EL including an organic material vulnerable to a high temperature atmosphere from being damaged.

The second encapsulation layer 462 may have an area or size smaller than the first encapsulation layer 461. For example, the second encapsulation layer 462 may be disposed to expose both ends or edges of the first encapsulation layer 461. The second encapsulation layer 462 can serve as a buffer for relieving stress between corresponding layers while the display device 100 is curved or bent, and also serve to enhance planarization performance. For example, the second encapsulation layer 462 may include an organic insulating material, such as acrylic resin, epoxy resin, polyimide, polyethylene, silicon oxycarbon (SiOC), or the like. The second encapsulation layer 462 may be disposed, for example, by an inkjet technique.

The third encapsulation layer 463 may be disposed over the substrate 111 over which the second encapsulation layer 462 is disposed such that the third encapsulation layer 463 covers the respective upper surfaces and side surfaces of the second encapsulation layer 462 and the first encapsulation layer 461. The third encapsulation layer 463 can serve to minimize or block external moisture or oxygen from penetrating into the first encapsulation layer 461 containing an inorganic material and the second encapsulation layer 462 containing an organic material. For example, the third encapsulation layer 463 may include an inorganic insulating material, such as silicon nitride (SiNx), silicon oxide (SiOx), silicon oxynitride (SiON), aluminum oxide (Al2O3), or the like.

At least one color filter 480 may be disposed on the third encapsulation layer 463. The color filter 480 may be disposed to overlap with the light emitting element ED. A black matrix 470 may be disposed between color filters 480 and/or between the third encapsulation layer 463 and the color filter 480.

In an example where color filters 480 are disposed in the display panel 110, a plurality of light emitting elements ED may emit light of a same color. For example, when the color filters 480 are disposed, the plurality of light emitting elements ED may emit the same white light. In another example, the plurality of light emitting elements ED may emit the same blue light.

For example, the color filters 480 may include a red color filter, a green color filter, and a blue color filter. However, embodiments of the present disclosure are not limited to these specific examples.

The touch sensing lines (not shown in the drawings) might be positioned between the encapsulation layer 460 and the color filters 480. The touch sensing lines might define a mesh structure, wherein one or more of the subpixels are arranged in opening areas of the mesh structure.

Meanwhile, light generated from the emission layer EL of the light emitting element ED may emit in various paths. Referring to FIG. 4, light generated from the emission layer EL of the light emitting element ED may pass through the encapsulation layer 460 and the color filter 480 and exit the display panel 110. However, some of the light generated from the emission layer EL may be trapped inside of the bank 450 or the encapsulation layer 460 through total reflection due to a difference in refractive index between layers. This situation can lead to emission efficiency to be reduced and hinder the display panel 110 from providing a uniform luminance quality to users.

In addition, some light emitted in directions different from a direction that is perpendicular to the substrate 111 may be more difficult to exit the display panel 110 due to total reflection as an angle to the direction perpendicular to the substrate 111 increases, this causing a corresponding viewing angle to be narrowed.

For example, light generated from the emission layer EL may circulate inside of the display panel 110 through internal total reflection, and thereby, the luminance and viewing angle of the display panel 110 may be degraded and narrowed.

According to one or more example embodiments of the present disclosure, the viewing angle narrowing issue and the luminance degradation issues can be addressed by disposing an insulating layer 500 and a convex insulating layer 510 between the second planarization layer 442 and the pixel electrode PE.

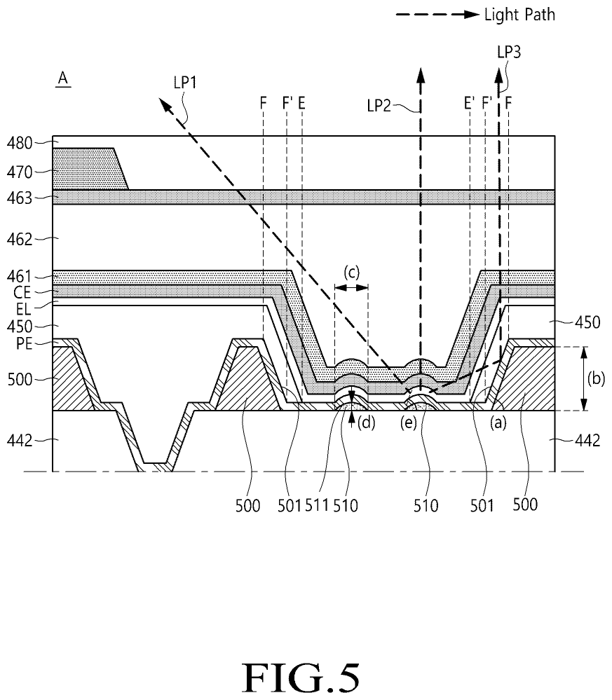

FIG. 5 is another example cross-sectional view of area A in FIG. 2 according to one embodiment.

For convenience of explanation, FIG. 5 illustrates a stackup configuration disposed on a second planarization layer 442, and a stackup configuration disposed under the second planarization layer 442 may be the same as the corresponding stackup configuration in the cross-sectional view of FIG. 4.

Referring to FIG. 5, an insulating layer 500 and a convex insulating layer 510 may be disposed between a pixel electrode PE and the second planarization layer 442. The insulating layer 500 may include the same material as the second planarization layer 442. The convex insulating layer 510 may include the same material as the second planarization layer 442. For example, the insulating layer 500 and the convex insulating layer 510 may include the same organic material as the second planarization layer 442, but aspects of the present disclosure are not limited thereto.

A stackup configuration disposed on the pixel electrode PE may be the same as that in the cross-sectional view of FIG. 4. That is, an emission layer EL may be disposed on the pixel electrode PE. A cathode electrode CE may be disposed on the emission layer EL. An encapsulation layer 460 may be disposed on the cathode electrode CE. At least one color filter 480 may be disposed on the third encapsulation layer 460. A black matrix 470 may be disposed between color filters 480 and/or between the third encapsulation layer 463 and the color filter 480.

In one or more aspects, the color filter 480 may overlap with a light emitting area EA. The color filter 480 may overlap with the convex insulating layer 510 disposed in the light emitting area EA. The touch sensing lines may not overlap with the convex insulating layers 510 (although not shown in the drawings).

Referring to FIG. 5, an area indicated by line E-E′ may be an area corresponding to the light emitting area EA shown in FIG. 4. The convex insulating layer 510 may be disposed in area E-E′. For example, the convex insulating layer 510 may be disposed to overlap with the light emitting area EA.

Referring to FIG. 5, the insulating layer 500 may be disposed such that the insulating layer 500 does not to overlap with the light emitting area EA. For example, the insulating layer 500 may have an opening overlapping with the light emitting area EA. The opening of the insulating layer 500 overlapping with the light emitting area EA may overlap with the area indicated by line E-E′ shown in FIG. 5.

The convex insulating layer 510 may be disposed in the opening of the insulating layer 500. The convex insulating layer 510 may be disposed in various shapes. For example, the convex insulating layer 510 may be disposed in a shape such as a circle, an oval, a polygon, or the like. In one or more embodiments, the convex insulating layer 510 may have an island shape. FIG. 5 illustrates an example where the convex insulating layer 510 is disposed in a circular shape so that light generated from the emission layer EL can be evenly directed in various directions. However, aspects of the present disclosure are not limited thereto.

The insulating layer 500 may have a height in a degree to which the pixel electrode PE can include an inclined portion 501 with an inclined surface. The convex insulating layer 510 may have a height less than the insulating layer 500. The inclined portion 501 of the pixel electrode PE may be disposed in the opening of the insulating layer 500 and may overlap with the opening of the insulating layer 500.

As the pixel electrode PE is disposed on the insulating layer 500 and the convex insulating layer 510, the pixel electrode PE may include the inclined portion 501 and a convex or curved portion 511 with a convex or curved surface formed along the insulating layer 500 and the curvature of the convex insulating layer 510.

The pixel electrode PE may include the inclined portion 501 as the pixel electrode PE is disposed along the curve of the insulating layer 500. Some of light generated from the emission layer EL may move at a direction at a certain angle to the substrate 111 of the display panel 110 (which may be referred to as “lateral direction”) rather than a direction perpendicular to the substrate 111 (which may be referred to as “vertical direction”). Some light moving in a lateral direction may be reflected by the inclined portion 501 of the pixel electrode PE formed along the insulating layer 500, and then, directed to exit the display panel 110, for example, in a path LP3.

Since the pixel electrode PE includes the inclined portion 501, a bank 450 disposed on the pixel electrode PE may be disposed to overlap with the inclined portion 501 of the pixel electrode PE. The bank 450 may be disposed to overlap with a portion of the pixel electrode PE including the inclined portion 501, and include a bank opening overlapping with the light emitting area EA.

As the pixel electrode PE is disposed along the curve of the convex insulating layer 510, the pixel electrode PE may include the convex or curved portion 511. Some of the light generated from the emission layer EL may move at a lateral direction, for example, in another path LP1.

For example, as the insulating layer 500 causes the pixel electrode PE to include the inclined portion 501, some light totally reflected by the bank 450 and the like among light generated from the emission layer EL may be directed to exit the display panel 110. Accordingly, the display panel 110 can provide an effect or advantage of increasing the luminance of the display panel 110.

Further, as the convex insulating layer 510 causes the pixel electrode PE to include the convex or curved portion 511, light can be emitted or directed at various angles by the convex or curved portion 511. Accordingly, the display panel 110 can provide an effect or advantage of raising the viewing angle.

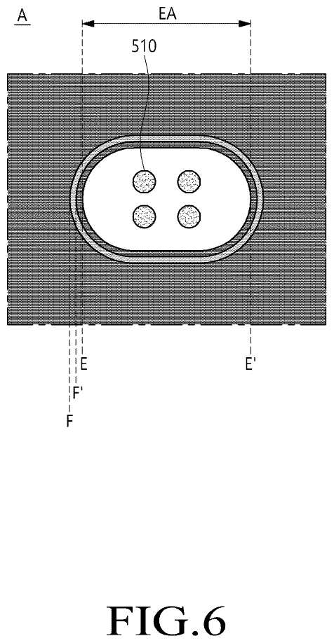

FIG. 6 is an example plan view of area A in FIG. 2 according to one embodiment.

The plan view shown in FIG. 6 is a plan view matching the stackup configuration of the cross-sectional view shown in FIG. 5.

Referring to FIGS. 5 and 6, area E-E′ may be an area corresponding to the light emitting area EA where the emission layer EL is disposed to overlap with the pixel electrode PE and the cathode electrode CE.

The convex insulating layer 510 may be disposed in the light emitting area EA. FIG. 6 illustrates an example where four convex insulating layers 510 are disposed in the light emitting area EA, but this is only an example for explaining and aspects of the present disclosure are not limited thereto. As described above with reference to FIG. 5, the convex insulating layer 510 may be disposed between the pixel electrode PE and the second planarization layer 442.

Referring to FIGS. 5 and 6, area F-F′ may be an area corresponding to the inclined portion 501 of the pixel electrode PE. Area F-F′ can emit light in a ring shape surrounding the light emitting area EA by light reflected from the inclined portion 501 of the pixel electrode PE. Accordingly, area E-E′ may be referred to as a main light emitting area, and area F-F′ may be referred to as a sub-light emitting area. Accordingly, a low-luminance or non-emitting area F′-E is present between the sub-light emitting area and the main light emitting area. In addition, since light is diffused and emitted in various directions in an area where the convex insulating layer 510 is disposed, an area overlapping with the convex insulating layer 510 may be referred to as a diffuse light emitting area.

In one or more aspects, the convex insulating layer 510 may be disposed over the entire display area DA including the flat area FA and the bending area BA. In one or more aspects, the convex insulating layer 510 may be formed in different shapes in the flat area FA and the bending area BA.

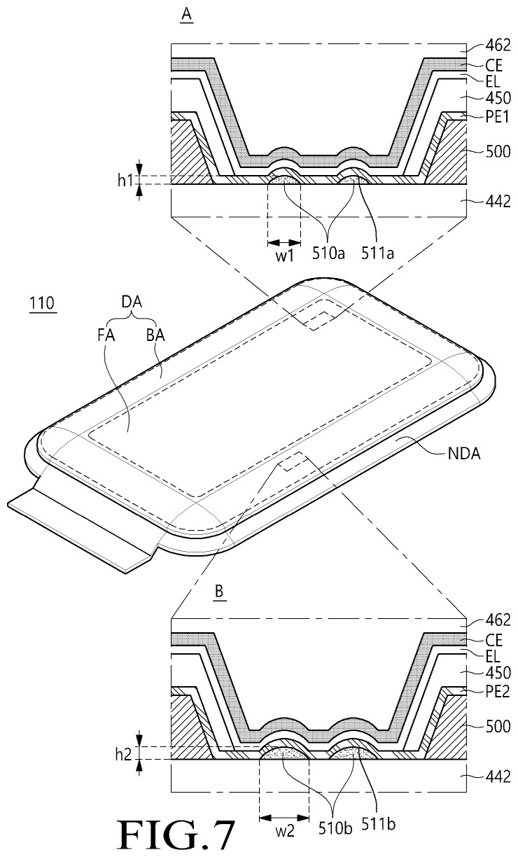

FIG. 7 illustrates respective example cross-sectional views of the flat area FA and the bending area BA of the display panel 100 according to embodiments of the present disclosure.

Referring to FIGS. 5 and 7, the insulating layer 500 and the convex insulating layer 510 shown in FIG. 5 may be disposed in the flat area FA and the bending area BA.

In one or more embodiments, the convex insulating layer 510 may be formed in different shapes in the flat area FA and the bending area BA.

Referring to FIG. 7, a convex insulating layer 510a disposed in the flat area FA may be disposed to have a first height h1 and a first width w1. A convex insulating layer 510b disposed in the bending area BA may be disposed to have a second height h2 and a second width w2.

In one or more embodiments, the second height h2 of the convex insulating layer 510b disposed in the bending area BA may be greater than the first height h1 of the convex insulating layer 510a disposed in the flat area FA. In one or more embodiments, the second width w2 of the convex insulating layer 510b disposed in the bending area BA may be greater than the first width w1 of the convex insulating layer 510a disposed in the flat area FA.

Since the size of the convex insulating layer 510b disposed in the bending area BA is greater than the size of the convex insulating layer 510a disposed in the flat area FA, the area of an upper surface of a convex or curved portion 511b of a second pixel electrode PE2 in the bending area BA may be greater than the area of an upper surface of a convex or curved portion 511a of a first pixel electrode PE1 in the flat area FA. In one or more aspects, the area of a lower surface of the convex insulating layer 510b disposed in the bending area BA may be greater than the area of a lower surface of the convex insulating layer 510a disposed in the flat area FA.

As the area of a convex or curved portion 511b of the second pixel electrode PE2 in the bending area BA is greater than the area of a convex or curved portion 511a of the first pixel electrode PE1 in the flat area FA, light emitted from the emission layer EL can be diffused more in the bending area BA than in the flat area FA. For example, as more light is emitted in directions different from the vertical direction in the bending area BA, the display panel 110 can provide an effect or advantage of raising a viewing angle in the bending area BA compared to the flat area FA.

Accordingly, even when the display panel 110 having four curved or bent sides, resulting in having curved or bent edges, this configuration can lead a viewing angle in the bending area BA to be wider than a viewing angle in the flat area FA, and thereby, the display panel 110 can provide an effect or advantage of enabling a user to recognize an image displayed on the display panel 110 without any sense of distinction due to a difference in luminance between the bending area BA and the flat area FA.

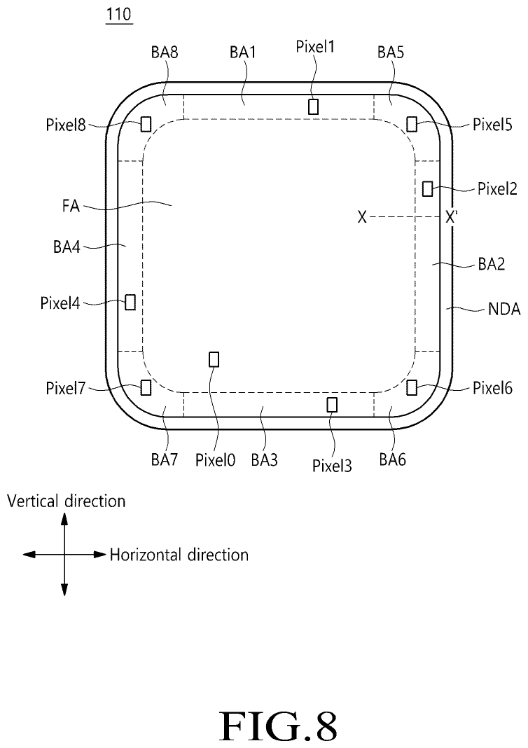

FIG. 8 is an example plan view of the display panel 100 according to embodiments of the present disclosure.

Referring to FIG. 8, the display panel 110 may include a flat area FA and a bending area BA, and the bending area BA may be formed such that a predefined curvature is applied from edges of the flat area FA of the display panel 110 to the bending area BA. Both the flat area FA and the bending area BA may be included in the display area DA. The non-display area NDA may be disposed on the outside or periphery of the display area DA.

The bending area BA may include a first bending area BA1 at an upper edge of the display panel 110 in the vertical direction in the plan view. The bending area BA may include a second bending area BA2 at a right edge of the display panel 110 in the horizontal direction in the plan view. The bending area BA may include a third bending area BA3 at a lower edge of the display panel 110 in the vertical direction in the plan view. The bending area BA may include a fourth bending area BA4 at a left edge of the display panel 110 in the horizontal direction in the plan view.

In one or more embodiments, the bending area BA may include a fifth bending area BA5 between the first bending area BA1 and the second bending area BA2. The bending area BA may include a sixth bending area BA6 between the second bending area BA2 and the third bending area BA3. The bending area BA may include a seventh bending area BA7 between the third bending area BA3 and the fourth bending area BA4. The bending area BA may include an eighth bending area BA8 between the fourth bending area BA4 and the first bending area BA1.

Respective convex insulating layers 510 disposed in the first to eighth bending areas (BA1, BA2, BA3, BA4, BA5, BA6, BA7, and BA8) may have various shapes.

The total area of the convex insulating layers 510 disposed in the bending areas (BA1, BA2, BA3, BA4, BA5, BA6, BA7, and BA8) may be greater than the total area of convex insulating layers 510 disposed in the flat area FA. For example, the total area of one or more convex insulating layers 510 disposed in any one or more pixels (e.g., Pixel1, and Pixel2, Pixel3, Pixel4, Pixel5, Pixel6, Pixel7, and/or Pixel8) included in the bending areas (BA1, BA2, BA3, BA4, BA5, BA6, BA7, and/or BA8) may be greater than the total area of a convex insulating layer disposed in any pixel Pixel0 included in the flat area FA.

As described above, when the display panel 110 includes at least one convex insulating layer 510, the display panel 110 can provide an effect or advantage of causing a viewing angle in an area where the convex insulating layer 510 is disposed to be raised. Since the total area of one or more convex insulating layers 510 of any one or more pixels (e.g., Pixel1, and Pixel2, Pixel3, Pixel4, Pixel5, Pixel6, Pixel7, and/or Pixel8) included in the bending areas (BA1, BA2, BA3, BA4, BA5, BA6, BA7, and/or BA8) is greater than the total area of the convex insulating layer of any pixel Pixel0 included in the flat area FA, the effect of raising a viewing angle in the bending area (BA1, BA2, BA3, BA4, BA5, BA6, BA7, and/or BA8) can become relatively greater. Accordingly, a viewing angle of the bending area (BA1, BA2, BA3, BA4, BA5, BA6, BA7, and/or BA8) may be greater than a viewing angle of the flat area FA.

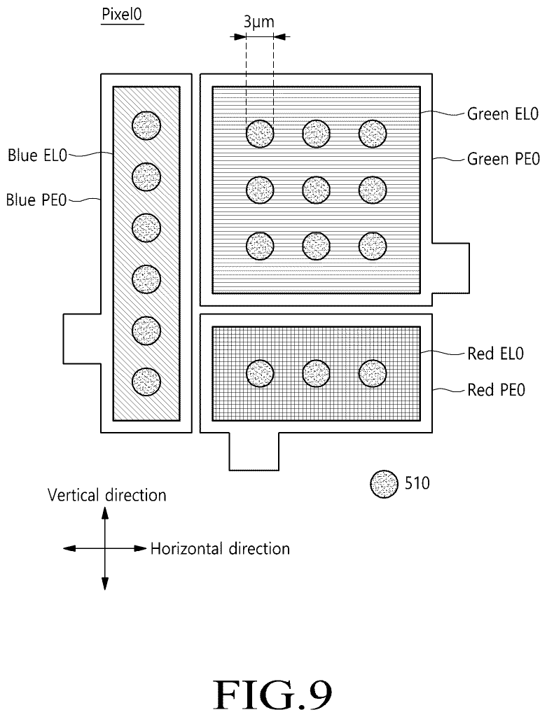

FIG. 9 is an example plan view of a zeroth pixel Pixel0 disposed in the flat area FA of the display panel 110 in FIG. 8 according to embodiments of the present disclosure.

Referring to FIG. 9, any zeroth pixel Pixel0 disposed in the flat area FA of the display panel 110 may include a zeroth red pixel electrode (Red PE0), a zeroth green pixel electrode (Green PE0), and a zeroth blue pixel electrode (Blue PE0).

A zeroth red emission layer (Red EL0) may be disposed on a zeroth red pixel electrode (Red PE0). A zeroth green emission layer (Green EL0) may be disposed on a zeroth green pixel electrode (Green PE0). A zeroth blue emission layer (Blue EL0) may be disposed on a zeroth blue pixel electrode (Blue PE0).

Red light may be emitted in an area where the zeroth red emission layer (Red EL0) is disposed. Green light may be emitted in an area where the zeroth green emission layer (Green EL0) is disposed. Blue light may be emitted in an area where the zeroth blue emission layer (Blue EL0) is disposed,

It may be understood that FIG. 9 illustrates a configuration where convex insulating layers 510 are disposed on the lower surface of each of the pixel electrodes (Red PE0, Green PE0, and Blue PE0).

Referring to FIG. 9, three convex insulating layers 510 may be disposed on the lower surface of the zeroth red pixel electrode (Red PE0). Nine convex insulating layers 510 may be disposed on the lower surface of the zeroth green pixel electrode (Green PE0). Six convex insulating layers 510 may be disposed on the lower surface of the zeroth blue pixel electrode (Blue PE0). For example, the number of convex insulating layers 510 may be different depending on a color of light emitted in the zeroth pixel Pixel0.

However, the number of convex insulating layers 510 disposed on the lower surface of each pixel electrode (Red PE0, Green PE0, and/or Blue PE0) is not limited thereto. The number of convex insulating layers 510 disposed on the lower surface of the zeroth red pixel electrode (Red PE0) is not limited to three, the number of convex insulating layers 510 disposed on the lower surface of the zeroth green pixel electrode (Green PE0) is not limited to nine, and the number of convex insulating layers 510 disposed on the lower surface of the zeroth blue pixel electrode (Blue PE0) is not limited to six. It should be noted that the number of convex insulating layers 510 may be set variously depending on an area of a convex insulating layer 510 disposed, a distance between convex insulating layers, and/or an area of a pixel electrode PE.

In one or more embodiments, the width of each convex insulating layer 510 disposed in the zeroth pixel Pixel0 may be about 3 μm, but not limited thereto. The width of the convex insulating layer 510 may mean the diameter of the convex insulating layer 510 in an example where the convex insulating layer 510 is circular. The width of the convex insulating layer 510 may mean a maximum width of the convex insulating layer 510 in one direction in an example where the convex insulating layer 510 is other shapes.

In one or more embodiments, even though not shown in FIG. 9, two or more data lines can overlap the pixel Pixel0 shown in FIG. 9, for example four data lines. In an exemplary embodiment, one of the overlapping data lines might overlap fully or partially the convex insulating layers 510 of the left column arranged on the green pixel electrode Green PE0 shown in FIG. 9 and the left convex insulating layer 510 arranged on the red pixel electrode Red PE0 shown in FIG. 9. None of the data lines might overlap the convex insulating layers 510 arranged on the blue pixel electrode Blue PE0.

In one exemplary embodiment, the data lines might be arranged on the second interlayer insulating layer 415 and separated from the convex insulating layer 510 by the first and second planarization layers 441, 442. In this configuration, even if one of the data lines only partially overlaps one or more of the convex insulating layers 510, it would not have an adverse effect on the shape of the overlapping convex insulating layer.

Even though the zeroth pixel PE0 is arranged in the flat area FA, the relative arrangement of the data lines with respect to the convex insulating layers 510 described above might also apply to any of the first to eighths pixels PE1 to PE8 arranged in the bending areas BA1 to BA8, respectively.

In one or more embodiments, even though not shown in FIGS. 4 and 5, the second source-drain electrode pattern 422 might overlap one or more of the convex insulating layers 510. In an exemplary embodiment, the second source-drain electrode pattern 422 might overlap only some of the convex insulating layers 510 arranged on the blue pixel electrode Blue PE0 shown in FIG. 9, for example the upper and lower convex insulating layers 510 shown in FIG. 9. Alternatively, the second source-drain electrode pattern 422 might not overlap any of the convex insulating layers 510 arranged on the blue pixel electrode Blue PE0. Optionally, the second source-drain electrode 422 might overlap all of the convex insulating layers 510 arranged on the red pixel electrode Red PE0 shown in FIG. 9. Further optionally, the second source-drain electrode pattern 422 might overlap some of the convex insulating layers 510 arranged on the green pixel electrode Green PE0 shown in FIG. 9, for example the convex insulating layers 510 arranged in the middle column of the convex insulating layers 510 arranged on the green pixel electrode Green PE0 shown in FIG. 9

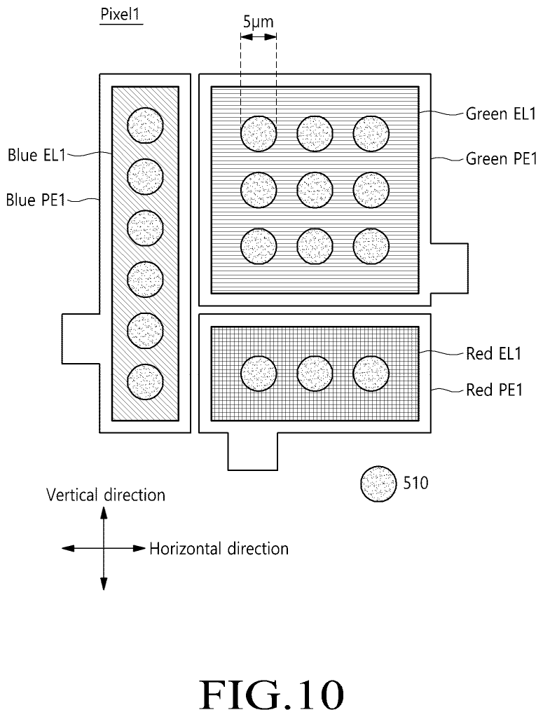

FIG. 10 is an example plan view of the first pixel Pixel1 disposed in the first bending area BA1 of the display panel 110 in FIG. 8 according to embodiments of the present disclosure.

Referring to FIG. 10 and FIG. 9, the structure of the first pixel Pixel1 disposed in the first bending area BA1 may be the same as the structure of the zeroth pixel Pixel0 disposed in the flat area FA except for the configuration of convex insulating layers 510.

For example, any first pixel Pixel1 disposed in the first bending area BA1 of the display panel 110 may include a first red pixel electrode (Red PE1), a first green pixel electrode (Green PE1), and a first blue pixel electrode (Blue PE1).

A first red emission layer (Red EL1) may be disposed on the first red pixel electrode (Red PE1). A first green emission layer (Green EL1) may be disposed on the first green pixel electrode (Green PE1). A first blue emission layer (Blue EL1) may be disposed on the first blue pixel electrode (Blue PE1).

Red light may be emitted in an area where the first red emission layer (Red EL1) is disposed. Green light may be emitted in an area where the first green emission layer (Green EL1) is disposed. Blue light may be emitted in an area where the first emission layer (Blue EL1) is disposed,

It may be understood that FIG. 10 illustrates a configuration where convex insulating layers 510 are disposed on the lower surface of each of the pixel electrodes (Red PE1, Green PE1, and Blue PE1).

Referring to FIG. 10, three convex insulating layers 510 may be disposed on the lower surface of the first red pixel electrode (Red PE1). Nine convex insulating layers 510 may be disposed on the lower surface of the first green pixel electrode (Green PE1). Six convex insulating layers 510 may be disposed on the lower surface of the first blue pixel electrode (Blue PE1). For example, the number of convex insulating layers 510 may be different depending on a color of light emitted in the first pixel Pixel1.

However, the number of convex insulating layers 510 disposed on the lower surface of each pixel electrode (Red PE1, Green PE1, and/or Blue PE1) is not limited thereto. The number of convex insulating layers 510 disposed on the lower surface of the first red pixel electrode (Red PE1) is not limited to three, the number of convex insulating layers 510 disposed on the lower surface of the zeroth first green pixel electrode (Green PE1) is not limited to nine, and the number of convex insulating layers 510 disposed on the lower surface of the first blue pixel electrode (Blue PE1) is not limited to six. It should be noted that the number of convex insulating layers 510 may be set variously depending on an area of a convex insulating layer 510 disposed, a distance between convex insulating layers 510, and/or an area of a pixel electrode PE.

In one or more embodiments, in the bending area BA including the first bending area BA1, as many convex insulating layers 510 as possible may be disposed in a range that can meet design and process requirements. In one or more embodiments, the number of convex insulating layers 510 disposed in the bending area BA, a distance between convex insulating layers 510, and an area of a pixel electrode PE may be adjusted to provide a wide viewing angle depending on the curvature of the bending area BA.

In one or more embodiments, the width of each convex insulating layer 510 disposed in the first pixel Pixel1 may be about 5 μm, but not limited thereto. The width of the convex insulating layer 510 may mean the diameter of the convex insulating layer 510 in an example where the convex insulating layer 510 is circular. The width of the convex insulating layer 510 may mean a maximum width of the convex insulating layer 510 in one direction in an example where the convex insulating layer 510 is other shapes.

Referring to FIGS. 9 and 10, in one or more embodiments, the width of each convex insulating layer 510 disposed in the flat area FA may be about 3 μm, and the width of each convex insulating layer 510 disposed in the first bending area BA1 may be about 5 μm. For example, the width of the convex insulating layer 510 disposed in the bending area BA may be greater than the width of the convex insulating layer 510 disposed in the flat area FA.

In one or more embodiments, the structure of the first pixel Pixel1 of the first bending area BA1 shown in FIG. 10 may have the same structure as the second pixel Pixel2 of the second bending area BA2, the third pixel Pixel3 of the third bending area BA3, the fourth pixel Pixel4 of the fourth bending area BA4, the fifth pixel Pixel5 of the fifth bending area BA5, the sixth pixel Pixel6 of the sixth bending area BA6, the seventh pixel Pixel7 of the seventh bending area BA7, and the eighth pixel Pixel8 of the eighth bending area BA8.

In this way, as the width of each convex insulating layer 510 disposed in the bending area BA is greater than the width of each convex insulating layer 510 disposed in the flat area FA, the display panel 110 can provide an effect or advantage of relatively widening a viewing angle in the bending area BA compared to a viewing angle in the flat area FA. Accordingly, the display panel 110 can provide an effect or advantage of alleviating the sense of separation that may be felt between the flat area FA and the bending area BA.

In one or more embodiments, the width of each convex insulating layer 510 disposed in the flat area FA and the width of each convex insulating layer 510 disposed in the bending area BA may be different from each other, and further, respective widths of convex insulating layers disposed in the bending area BA may be different from each other.

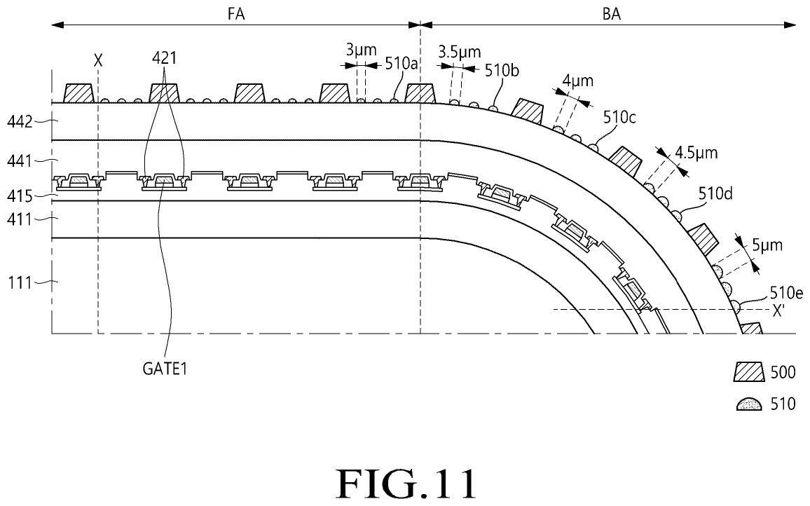

FIG. 11 is an example cross-sectional view taken along line X-X′ of the display panel 110 in FIG. 8 according to embodiments of the present disclosure.

The cross-sectional configuration taken along line X-X′ in the display panel 110 shown in FIG. 11 may be the same as the configuration of FIG. 4. For convenience of explanation, FIG. 11 illustrates a simplified stackup configuration in which some layers or elements are omitted.

The flat area FA of the display panel 110 may include a first convex insulating layer 510a. The bending area BA of the display panel 110 may include a second convex insulating layer 510b, a third convex insulating layer 510c, a fourth convex insulating layer 510d, and a fifth convex insulating layer 510e. The second convex insulating layer 510b may be disposed at a further distance from the center of the display panel 110 than the first convex insulating layer 510a. The third convex insulating layer 510c may be disposed at a further distance from the center of the display panel 110 than the second convex insulating layer 510b. The fourth convex insulating layer 510d may be disposed at a further distance from the center of the display panel 110 than the third convex insulating layer 510c. The fifth convex insulating layer 510e may be disposed at a further distance from the center of the display panel 110 than the fourth convex insulating layer 510d.

It should be noted that the cross-sectional view of the display panel 110 including the convex insulating layer 510 shown in FIG. 11 may not be based on an actual scale of the display panel 110. For convenience of explanation, FIG. 11 illustrates a configuration similar to a configuration of an actual display panel.

The width of the first convex insulating layer 510a disposed in the flat area FA may be about 3 μm. The width of the second convex insulating layer 510b disposed in the bending area BA may be greater than that of the first convex insulating layer 510a. For example, the width of the second convex insulating layer 510b may be about 3.5 μm.

The width of the third convex insulating layer 510c disposed in the bending area BA may be greater than the width of the second convex insulating layer 510b. For example, the width of the third convex insulating layer 510c may be about 4 μm.

The width of the fourth convex insulating layer 510d disposed in the bending area BA may be greater than the width of the third convex insulating layer 510c. For example, the width of the fourth convex insulating layer 510d may be about 4.5 μm.

The width of the fifth convex insulating layer 510e disposed in the bending area BA may be greater than the width of the fourth convex insulating layer 510d. For example, the width of the fifth convex insulating layer 510e may be about 5 μm.

For example, the widths of the convex insulating layers 510 disposed in the bending area BA may be greater as a distance from the center of the display panel 110 increases.

Since a predefined curvature is applied to the bending area BA of the display panel 110, an angle between the bending area BA and a viewing surface on which a user looks at an image may more increase as a distance from the center of the display panel 110 increases. Therefore, the widths of the convex insulating layers 510 disposed in the bending area BA may be designed to more increase as a distance from the center of the display panel 110 increases, thereby, resulting in a corresponding viewing angle being gradually increased.

Accordingly, the display panel 110 can provide an effect or advantage of maintaining uniform image quality even in the bending area BA.

In one or more aspects, respective shapes of convex insulating layers 510 may be differentially designed so that a user can perceive image quality uniformly as a distance from the center of the display panel 110 increases in the bending area BA.

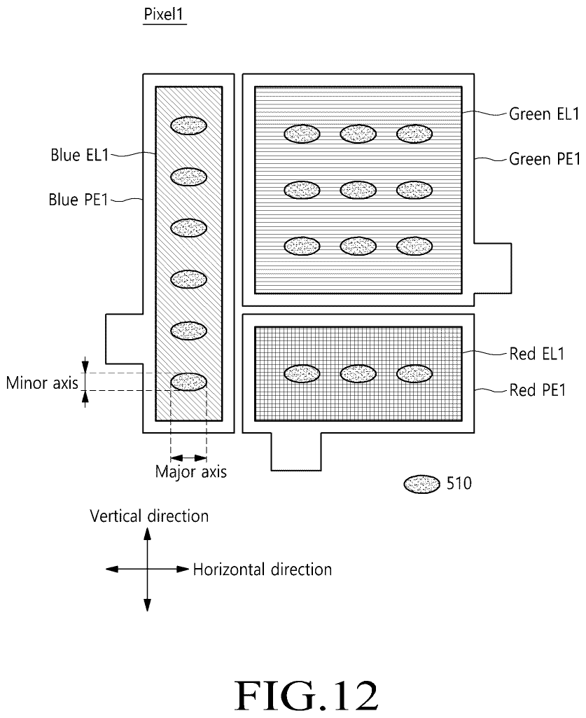

FIG. 12 is another example plan view of the first pixel Pixel1 disposed in the first bending area BA1 of the display panel 110 in FIG. 8 according to embodiments of the present disclosure.

Referring to FIG. 12, the structure of the first pixel Pixel1 disposed in the first bending area BA1 of the display panel 110 may be the same as the structure of the zeroth pixel Pixel0 disposed in the flat area FA described above except for the configuration of convex insulating layers 510.

For example, any first pixel Pixel1 disposed in the first bending area BA1 of the display panel 110 may include a first red pixel electrode (Red PE1), a first green pixel electrode (Green PE1), and a first blue pixel electrode (Blue PE1).

A first red emission layer (Red EL1) may be disposed on the first red pixel electrode (Red PE1). A first green emission layer (Green EL1) may be disposed on the first green pixel electrode (Green PE1). A first blue emission layer (Blue EL1) may be disposed on the first blue pixel electrode (Blue PE1).

Red light may be emitted in an area where the first red emission layer (Red EL1) is disposed. Green light may be emitted in an area where the first green emission layer (Green EL1) is disposed. Blue light may be emitted in an area where the first blue emission layer (Blue EL1) is disposed,

It may be understood that FIG. 12 illustrates a configuration where convex insulating layers 510 are disposed on the lower surface of each of the pixel electrodes (Red PE1, Green PE1, and Blue PE1).

Referring to FIG. 12, three convex insulating layers 510 may be disposed on the lower surface of the first red pixel electrode (Red PE1). Nine convex insulating layers 510 may be disposed on the lower surface of the first green pixel electrode (Green PE1). Six convex insulating layers 510 may be disposed on the lower surface of the first blue pixel electrode (Blue PE1). For example, the number of convex insulating layers 510 may be different depending on a color of light emitted in the first pixel Pixel1.

However, the number of convex insulating layers 510 disposed on the lower surface of each pixel electrode (Red PE1, Green PE1, and/or Blue PE1) is not limited thereto. The number of convex insulating layers 510 disposed on the lower surface of the first red pixel electrode (Red PE1) is not limited to three, the number of convex insulating layers 510 disposed on the lower surface of the zeroth first green pixel electrode (Green PE1) is not limited to nine, and the number of convex insulating layers 510 disposed on the lower surface of the first blue pixel electrode (Blue PE1) is not limited to six. It should be noted that the number of convex insulating layers 510 may be set variously depending on an area of a convex insulating layers 510 disposed, a distance between convex insulating layers 510, and an area of a pixel electrode PE.

The shape of the convex insulating layers 510 disposed in the first pixel Pixel1 may be oval. For example, the convex insulating layers 510 may have an oval shape with a major axis in the horizontal direction and a minor axis in the vertical direction based on the front surface of the display panel 110.

The structure of the first pixel Pixel1 of the first bending area BA1 shown in FIG. 12 may be substantially equally applied to the third pixel Pixel3 of the third bending area BA3 in the structure of the bending area BA as in FIG. 8.

Since each convex insulating layer 510 disposed in the first pixel Pixel1 of the first bending area BA1 has an oval shape with a major axis in the horizontal direction, when compared to having a circular shape, the display panel 110 can provide an effect or advantage of raising a viewing angle in the vertical direction.

The shape of the convex insulating layers 510 disposed in the first pixel Pixel1 of the first bending area BA1 may be the same as the shape of convex insulating layers 510 disposed in the third pixel Pixel3 of the third bending area BA3.

In one or more embodiments, to provide a user with the bending area BA of the display panel 110 configured with uniform luminance by raising a viewing angle in the horizontal direction, second and fourth bending areas (BA2 and BA4) may be designed to have a major axis in the vertical direction.

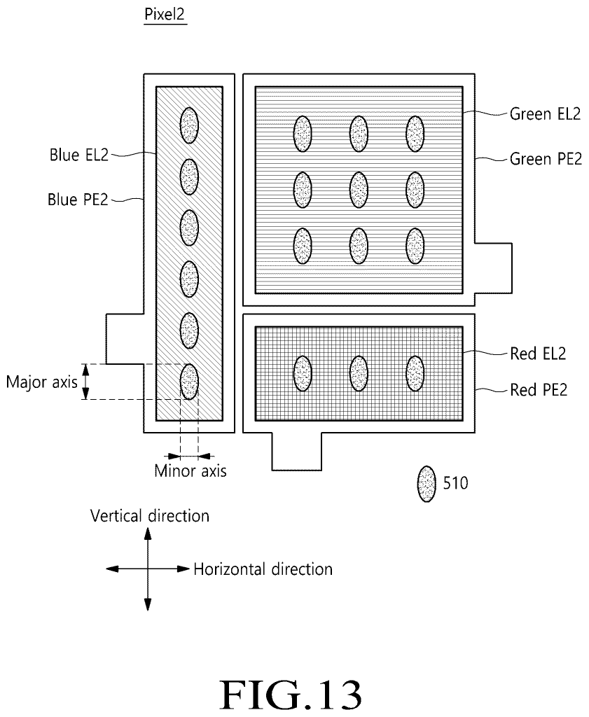

FIG. 13 is an example plan view of the second pixel Pixel2 disposed in the second bending area BA2 of the display panel 110 in FIG. 8 according to embodiments of the present disclosure.

The configuration of the second pixel Pixel2 shown in FIG. 13 may be the same as the configuration of the first pixel Pixel1 shown in FIG. 12 except for the configuration of convex insulating layers 510 disposed in the second bending area BA2. The structure of the second pixel Pixel2 shown in FIG. 13 may be substantially equally applied to the fourth pixel Pixel4 of the fourth bending area BA4 in the structure of the bending area BA as in FIG. 8.

It should be noted that compared to the first pixel Pixel1 shown in FIG. 12, which includes the convex insulating layers 510 with a major axis in the horizontal direction to raise a viewing angle in the vertical direction, the second pixel Pixel2 may have convex insulating layers 510 with a major axis in the vertical direction to raise a viewing angle in the horizontal direction.

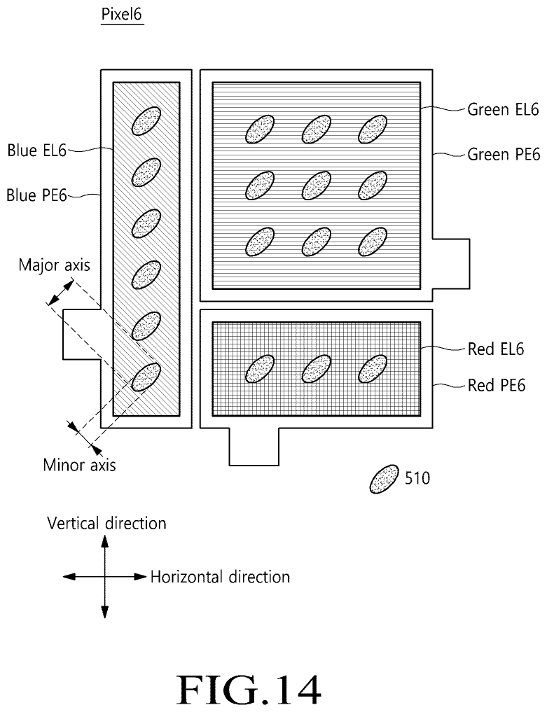

FIG. 14 is an example plan view of the sixth pixel Pixel6 disposed in the sixth bending area BA6 of the display panel 110 in FIG. 8 according to embodiments of the present disclosure.

The configuration of the sixth pixel Pixel6 shown in FIG. 14 may be the same as the configuration of the second pixel Pixel2 shown in FIG. 13 except for the configuration of convex insulating layers 510 disposed in the sixth pixel Pixel6. The structure of the sixth pixel Pixel6 shown in FIG. 14 may be substantially equally applied to the eighth pixel Pixel8 of the eighth bending area BA8 in the structure of the bending area BA as in FIG. 8.

It should be noted that compared to the second pixel Pixel2 shown in FIG. 13, which includes the convex insulating layers 510 with a major axis in the vertical direction to raise a viewing angle in the horizontal direction, to raise a viewing angle in a direction parallel to a direction connected to the center of the display panel 110, the sixth pixel Pixel6 may have convex insulating layers 510 with a major axis in a diagonal direction, which is a direction perpendicular to the direction connected to the center of the display panel 110.

In one or more embodiments, convex insulating layers 510 with an oval shape disposed in the bending area BA shown in FIGS. 12, 13, and 14 may be disposed in different shapes and/or patterns depending on a distance from the center of the display panel 110.

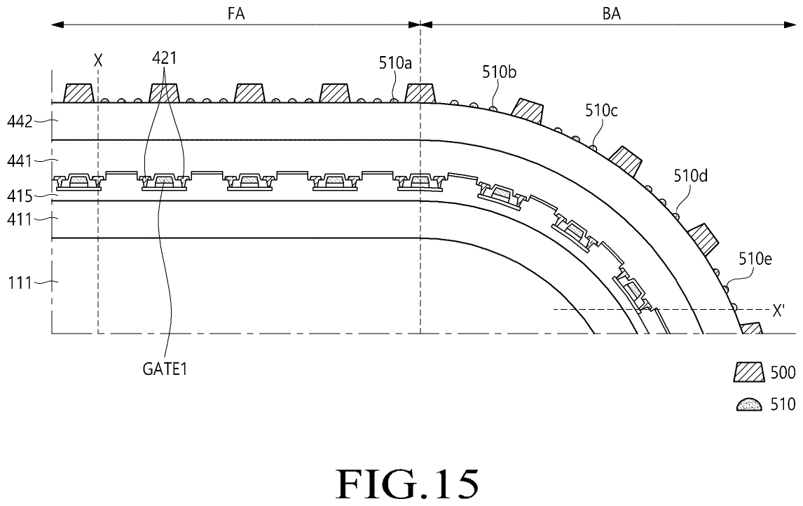

FIG. 15 is another example cross-sectional view taken along line X-X′ of the display panel 110 in FIG. 8 according to embodiments of the present disclosure.

The cross-sectional configuration taken along line X-X′ in the display panel 110 shown in FIG. 15 may be the same as the configuration of FIG. 4. For convenience of explanation, FIG. 15 illustrates a simplified stackup configuration in which some layers or elements are omitted.

The flat area FA of the display panel 110 may include a first convex insulating layer 510a. The bending area BA of the display panel 110 may include a second convex insulating layer 510b, a third convex insulating layer 510c, a fourth convex insulating layer 510d, and a fifth convex insulating layer 510e. The second convex insulating layer 510b may be disposed at a further distance from the center of the display panel 110 than the first convex insulating layer 510a. The third convex insulating layer 510c may be disposed at a further distance from the center of the display panel 110 than the second convex insulating layer 510b. The fourth convex insulating layer 510d may be disposed at a further distance from the center of the display panel 110 than the third convex insulating layer 510c. The fifth convex insulating layer 510e may be disposed at a further distance from the center of the display panel 110 than the fourth convex insulating layer 510d.

It should be noted that the cross-sectional view of the display panel 110 including the convex insulating layer 510 shown in FIG. 15 may not be based on an actual scale of the display panel 110. For convenience of explanation, FIG. 15 illustrates a configuration similar to a configuration of an actual display panel.

The first convex insulating layer 510a disposed in the flat area FA may have a circular shape. The second convex insulating layer 510b disposed in the bending area BA may have an oval shape with a major axis in a direction parallel to an edge of the display panel 110.

The third convex insulating layer 510c disposed in the bending area BA may have an oval shape with a major axis in a direction parallel to an edge of the display panel 110. In one or more aspects, the length of the major axis of the third convex insulating layer 510c may be greater than the length of the major axis of the second convex insulating layer 510b.

The fourth convex insulating layer 510d disposed in the bending area BA may have an oval shape with a major axis in a direction parallel to an edge of the display panel 110. In one or more aspects, the length of the major axis of the fourth convex insulating layer 510d may be greater than the length of the major axis of the third convex insulating layer 510c.

The fifth convex insulating layer 510e disposed in the bending area BA may have an oval shape with a major axis in a direction parallel to an edge of the display panel 110. In one or more aspects, the length of the major axis of the fifth convex insulating layer 510e may be greater than the length of the major axis of the fourth convex insulating layer 510d.

For example, the widths of the convex insulating layers 510 disposed in the bending area BA may have the oval shape in which a length of the major axis of the convex insulating layers 510 becomes greater as a distance from the center of the display panel 110 increases.

Since a predefined curvature is applied to the bending area BA of the display panel 110, an angle between the bending area BA and a viewing surface on which a user looks at an image may more increase as a distance from the center of the display panel 110 increases. To address this issue, as the convex insulating layers 510 disposed in the bending area BA are designed to have an oval shape, and the length of the major axis of the convex insulating layers 510 is designed to become greater as a distance from the center of the display panel 110 increases, the viewing angle of the display panel 110 can be gradually raised.

Accordingly, the display panel 110 can provide an effect or advantage of maintaining uniform image quality even in the bending area BA.

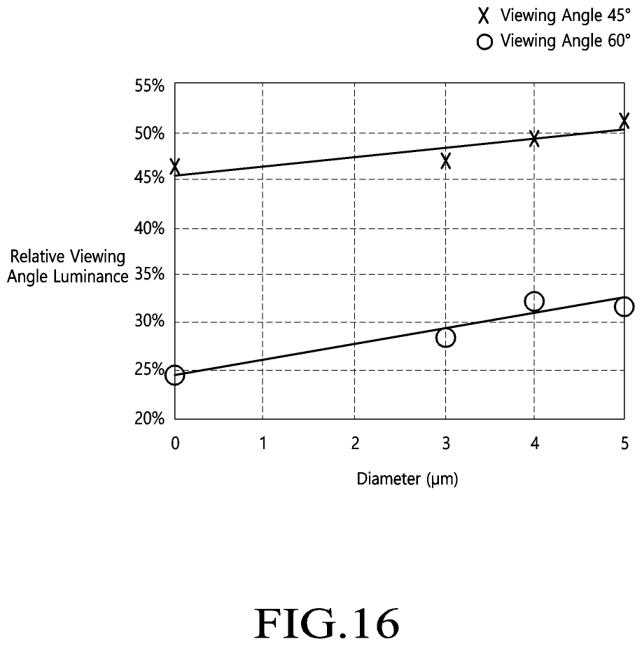

FIG. 16 is an example graph showing how luminance on a side or edge of the display panel 110 relative to luminance in the vertical direction of the display panel 110 is changed with respect to the diameter of convex insulating layers according to aspects of the present disclosure.

The x-axis of the graph shown in FIG. 16 may be a value representing the width of a convex insulating layer 510. When the convex insulating layer 510 has a circular shape, the width of the convex insulating layer 510 may have the same meaning as the diameter.

The y-axis of the graph shown in FIG. 16 may be a value representing luminance measured in a side or edge of the display panel 110 relative to luminance in the vertical direction of the display panel 110 (which may be referred to as a frontal luminance). For example, when a y-axis value is 50%, this may represent a luminance of 50% of the frontal luminance.

Referring to FIG. 16, luminance measured at a 45° viewing angle to a direction facing the center of the display panel 110 may be approximately 45% of the frontal luminance measured when the convex insulating layer 510 is not disposed, that is, when the diameter of the convex insulating layer 510 is 0 μm.

Referring to FIG. 16, luminance measured at a 45° viewing angle to a direction facing the center of the display panel 110 may increase as the diameter of the convex insulating layer 510 increases. For example, when the diameter of the convex insulating layer 510 is 5 μm, corresponding luminance may be about 50% of the frontal luminance.

Referring to FIG. 16, luminance measured at a 60° viewing angle to a direction facing the center of the display panel 110 may be approximately 25% of the frontal luminance measured when the convex insulating layer 510 is not disposed, that is, when the diameter of the convex insulating layer 510 is 0 μm.

Referring to FIG. 16, luminance measured at a 60° viewing angle to a direction facing the center of the display panel 110 may increase as the diameter of the convex insulating layer 510 increases. For example, when the diameter of the convex insulating layer 510 is 5 μm, corresponding luminance may be about 33% of the frontal luminance.

Referring to the graph shown in FIG. 16, it can be seen that a viewing angle in an area where the convex insulating layer 510 is disposed is raised, and as the diameter or width of the convex insulating layer 510 is greater, the effect of raising the viewing angle can be further enhanced.

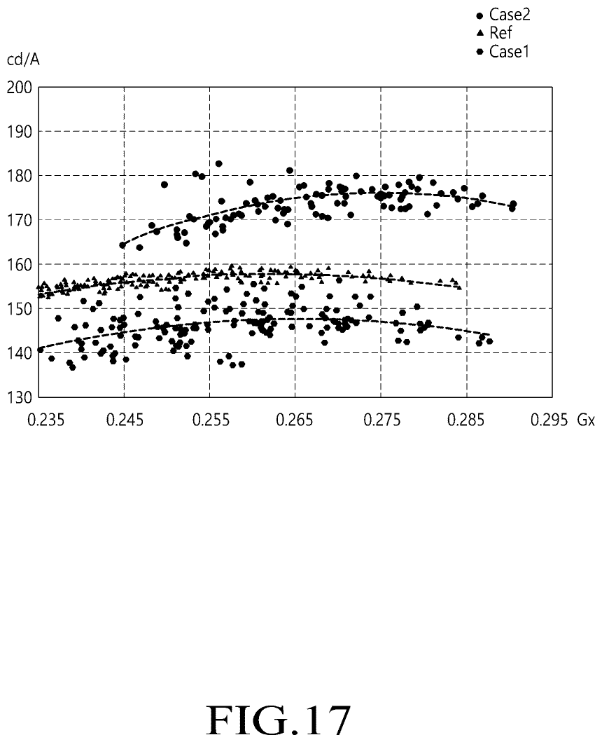

FIG. 17 is an example graph showing an amount of light emitted per current with respect to x values of green in CIE color coordinates measured in the display panel 110 in each case according to embodiments of the present disclosure.

The x-axis of the graph shown in FIG. 17 may represent values of the x-coordinate of green in the CIE color coordinates, and the y-axis may represent the intensity of light per current, which may be represented as candela/ampere (cd/A).

Referring to FIG. 17, an amount of light with respective to the CIE color coordinates of green in a reference case Ref where neither an insulating layer 500 nor a convex insulating layer 510 is disposed on the display panel 110, a first case Case1 where an insulating layer 500 is not disposed but at least one convex insulating layer 510 is disposed in the display panel 110, and a second case Case2 where both at least one insulating layer 500 and at least one convex insulating layer 510 are disposed in the display panel 110.

In the reference case Ref where neither an insulating layer 500 nor a convex insulating layer 510 is disposed, an amount of light emitted per current of green light may be approximately 150 cd/A to 160 cd/A.

In the first case Case1 where an insulating layer 500 is not disposed but at least one convex insulating layer 510 is disposed in the display panel 110, an amount of light emitted per current of green light may be approximately 140 cd/A to 150 cd/A.

In the second case Case2 where both at least one insulating layer 500 and at least one convex insulating layer 510 are disposed in the display panel 110, an amount of light emitted per current of green light may be approximately 165 cd/A to 180 cd/A.

Since the convex insulating layer 510 diffuses light emitted from a corresponding emission layer instead of widening the viewing angle, the amount of light measured in the first case Case 1 where only the convex insulating layer 510 is disposed may be reduced compared to the reference case Ref where a convex insulating layer 510 is not disposed.

In contrast, the amount of light measured in the second case Case2 where both the convex insulating layer 510 configured to widen the viewing angle and the insulating layer 500 configured to prevent light generated from the emission layer EL from being totally reflected inside of the display panel 110 and improve luminance are disposed may be increased compared to the reference case Ref.

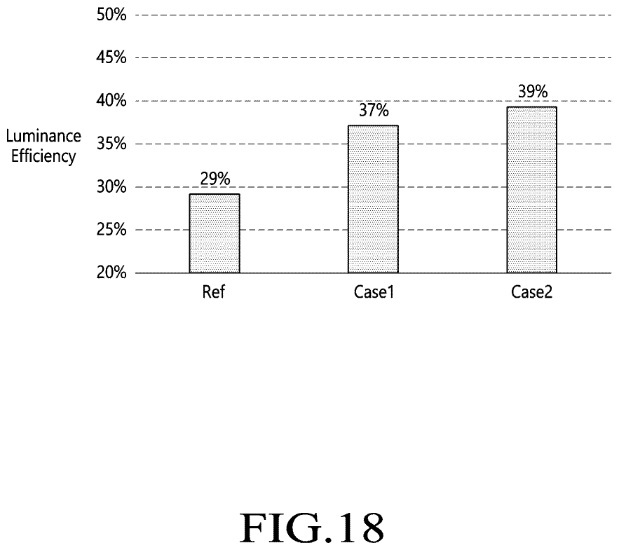

FIG. 18 is an example graph showing luminance efficiency of the display panel 110 at a 60° viewing angle in each case according to embodiments of the present disclosure.

Referring to FIG. 18, the reference case Ref may represent luminance efficiency at a 60° viewing angle of the display panel 110 in which neither an insulating layer 500 nor a convex insulating layer 510 is disposed. The first case Case1 may represent luminance efficiency at a 60° viewing angle of the display panel 110 in which an insulating layer 500 is not disposed but at least one convex insulating layer 510 is disposed. The second case Case2 may represent luminance efficiency at a 60° viewing angle of the display panel 110 in which both at least one insulating layer 500 and at least one convex insulating layer 510 are disposed.

Referring to FIG. 18, the luminance efficiency at a 60° viewing angle observed in the second case Case 2 where both the insulating layer 500 and the convex insulating layer 510 are disposed may be the highest, compared to the reference case Ref where neither the insulating layer 500 nor the convex insulating layer 510 is disposed and the first case Case1 where only the convex insulating layer 510 is disposed.

Referring to FIG. 18, the display panel 110 can provide effects or advantages of preventing light from being totally reflected into the display panel 110 as at least one insulating layer 500 is disposed, thereby increasing an amount of light, and diffusing the light as at least one convex insulating layer 510 is disposed, thereby providing a wider viewing angle.

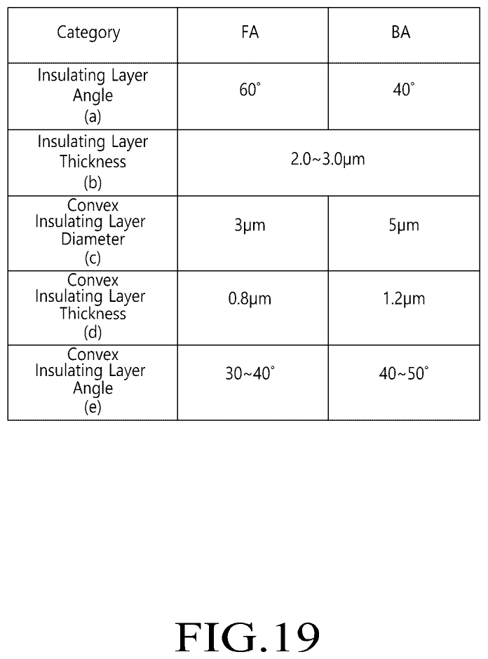

FIG. 19 is a table showing example configurations of insulating layers 500 and convex insulating layers 510 respectively disposed in the flat area FA and the bending area BA according to aspects of the present disclosure.

In the flat area FA, an angle (a) of an insulating layer 500 to a second planarization layer 442 (e.g., the second planarization layer 442 in the figures discussed above) may be 60°. A thickness (b) of the insulating layer 500 disposed in the flat area FA may be 2 μm to 3 μm. For example, the thickness (b) of the insulating layer 500 may have the same meaning as the height of the insulating layer 500.

In the bending area BA, an angle (a) of an insulating layer 500 to the second planarization layer 442 may be 40°. A height (b) of the insulating layer 500 disposed in the bending area BA may be 2 μm to 3 μm.

In order to provide a user with uniform image quality in the bending area BA, raising the viewing angle rather than improving luminance by the insulating layer 500 can provide a maximized effect. To this end, an angle of the insulating layer 500 to the second planarization layer 442 may be set to a smaller value.

A diameter (c) of a convex insulating layer 510 disposed in the flat area FA may be 3 μm. A thickness (d) of the convex insulating layer 510 disposed in the flat area FA may be 0.8 μm. In the flat area FA, an angle (e) of the convex insulating layer 510 to the planarization layer 442 may be 30° to 40°.

A diameter (c) of a convex insulating layer 510 disposed in the bending area BA may be 5 μm. A thickness (d) of the convex insulating layer 510 disposed in the bending area BA may be 1.2 μm. In bending area BA, an angle (e) of the convex insulating layer 510 to the planarization layer 442 may be 40° to 50°.

In order to provide a user with uniform image quality between the flat area FA and the bending area BA, the diameter (c), thickness (d), and angle (e) of the convex insulating layer 510 disposed in the bending area BA may be set to larger values than those of the convex insulating layer 510 disposed in the flat area FA. This can result in a wider viewing angle in the bending area BA, and therefore, the display device 110 can provide effects or advantages of addressing an issue in which image quality is degraded due to the curvature in the bending area BA.

In an exemplary embodiment, the angles on opposite sides of the convex insulating layers might be different, e.g., they might differ by 1-5°. For example, an angle α1 on a first side of a convex insulating layer is larger than an angle α2 on an opposite side of the convex insulating layer.

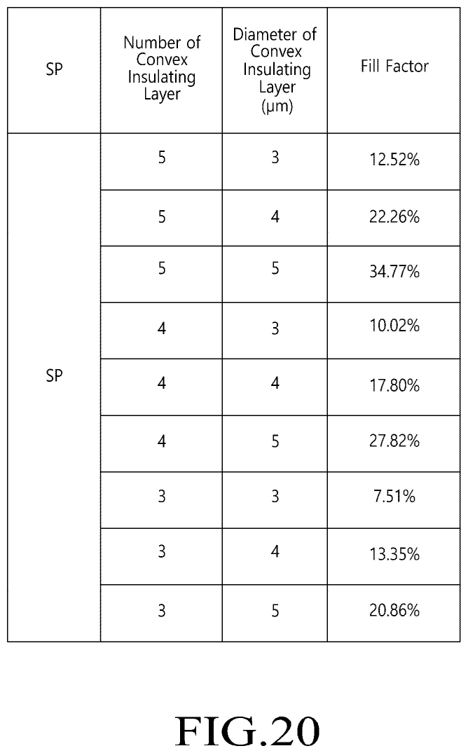

FIG. 20 is a table showing the number and diameter of convex insulating layers 510 disposed on a red subpixel, and a relevant fill factor according to aspects of the present disclosure.

The fill factor shown in the table may be a value obtained by dividing the area of a convex insulating layer 510 disposed in a light emitting element ED by an emission area formed by the light emitting element ED. The emission area may have the same meaning as the light emitting area EA. As the area of the convex insulating layer 510 overlapping with the emission area increases, the fill factor may increase.

Referring to the table shown in FIG. 20, the fill factor may increase as the number of convex insulating layers disposed in a subpixel SP increases. Further, the fill factor may increase as the diameter of the convex insulating layer 510 disposed in the subpixel SP increases.

According to the characteristics of the convex insulating layer 510 described above, as the area, height, angle, and the like increases relative to the diameter of the convex insulating layer 510, the display panel can provide effects or advantages of increasing the fill factor and raising a viewing angle. Accordingly, the shape of the convex insulating layer 510 may be adjusted so that the fill factor in the bending area BA can be greater than the fill factor in the flat area FA.

The display device according to the example embodiments herein can be described as follows.

According to the one or more example embodiments described herein, a display device can be provided that includes a substrate including a flat area and a bending area, a planarization layer disposed on the substrate, a first pixel electrode located in the flat area and disposed in a pixel electrode layer on the planarization layer, a second pixel electrode located in the bending area and disposed in the pixel electrode layer on the planarization layer, an insulating layer disposed between the planarization layer and the pixel electrode layer, and including a first opening overlapping with a portion of the first pixel electrode and a second opening overlapping with a portion of the second pixel electrode, at least one first convex insulating layer disposed on the planarization layer, located in an island shape in the first opening, and having a convex shape, and at least one second convex insulating layer disposed on the planarization layer, located in an island shape in the second opening, and having a convex shape. In one or more aspects, the first pixel electrode may include a first curved portion disposed along an upper surface of the at least one first convex insulating layer in the first opening, and the second pixel electrode may include a second curved portion disposed along an upper surface of the at least one second convex insulating layer in the second opening. In one or more aspects, an area of a lower surface of the at least one second convex insulating layer may be greater than that of a lower surface of the at least one first convex insulating layer in a plan view.

In one or more embodiments, an area of a lower surface of the at least one second convex insulating layer may be greater than that of a lower surface of the at least one first convex insulating layer.

In one or more embodiments, the first pixel electrode may include a first inclined portion extending along a side surface of the insulating layer in the first opening, and the second pixel electrode may include a second inclined portion extending along a side surface of the insulating layer in the second opening.

In one or more embodiments, the display device may further include a bank disposed on the first pixel electrode and the second pixel electrode. In one or more aspects, the bank may include a first bank opening overlapping with the first inclined portion and the second inclined portion and located in the first opening, and a second bank opening located in the second opening.

In one or more embodiments, the insulating layer may include a same material as the planarization layer.

In one or more embodiments, the at least one first convex insulating layer and the at least one second convex insulating layer may include a same material as the planarization layer.

In one or more embodiments, a height of the insulating layer may be greater than those of the at least one first convex insulating layer and the at least one second convex insulating layer.

In one or more embodiments, a surface area of the upper surface of the at least one first convex insulating layer may be less than that of the upper surface of the at least one second convex insulating layer.

In one or more embodiments, a height of the at least one first convex insulating layer may be less than that of the at least one second convex insulating layer.

In one or more embodiments, the at least one first convex insulating layer may overlap with the first pixel electrode, and the at least one second convex insulating layer may overlap with the second pixel electrode.

In one or more embodiments, the display device may further include a third pixel electrode disposed in the flat area, and at least one third convex insulating layer overlapping with the third pixel electrode. In one or more embodiments, a color of light emitted from an emission layer on the first pixel electrode and a color of light emitted from an emission layer on the third pixel electrode may be different from each other, and the number of the at least one first convex insulating layer (e.g., one or more of first convex insulating layers) and the number of the at least one third convex insulating layer (e.g., one or more of third convex insulating layers) may be different from each other.

In one or more embodiments, the color of the light emitted from the emission layer on the first pixel electrode may be green, and the color of the light emitted from the emission layer on the third pixel electrode may be red or blue. In one or more embodiments, the number of the at least one first convex insulating layer (e.g., one or more of first convex insulating layers) may be greater than the number of the at least one third convex insulating layer (e.g., one or more of third convex insulating layers).

In one or more embodiments, the color of the light emitted from the emission layer on the first pixel electrode may be blue, and the color of the light emitted from the emission layer on the third pixel electrode may be red. In one or more embodiments, the number of the at least one first convex insulating layer (e.g., one or more of first convex insulating layers) may be greater than the number of the at least one third convex insulating layer (e.g., one or more of third convex insulating layers).

In one or more embodiments, the display device may further include a fourth pixel electrode disposed in the bending area and spaced apart from the second pixel electrode, and at least one fourth convex insulating layer overlapping with the fourth pixel electrode. In one or more embodiments, a size of the at least one second convex insulating layer may be different from that of the at least one fourth convex insulating layer.

In one or more embodiments, the size of the at least one second convex insulating layer may be less than that of the at least one fourth convex insulating layer.

In one or more embodiments, each of the at least one second convex insulating layer and the at least one fourth convex insulating layer may have an oval shape, and a length of a major axis of the at least one second convex insulating layer may be less than that of a major axis of the at least one fourth convex insulating layer.

In one or more embodiments, the total area of the at least one second convex insulating layer disposed in the bending area may be greater than that of the at least one first convex insulating layer disposed in the flat area.

In one or more embodiments, a viewing angle of the bending area may be greater than that of the flat area.

In one or more embodiments, the display device may further include an encapsulation layer disposed on the first pixel electrode and the second pixel electrode, and a color filter layer disposed on the encapsulation layer. In one or more aspects, at least a portion of each of a plurality of color filters included in the color filter layer may overlap with the first convex insulating layer or the second convex insulating layer.

According to the one or more example embodiments described herein, a display device can be provided that includes a substrate on which a plurality of subpixels are disposed, a plurality of main light emitting areas overlapping with the plurality of subpixels, a plurality of sub-light emitting areas surrounding the plurality of main light emitting areas, wherein at least one diffuse light emitting area is included in each of the plurality of main light emitting areas. In one or more aspects, light emitted from the at least one diffuse light emitting area may have an emission angle that is not perpendicular to the substrate.

In one or more embodiments, the display device may further include a pixel electrode overlapping with at least one of the plurality of main light emitting areas and at least one of the plurality of sub-light emitting areas, and at least one convex insulating layer disposed such that the at least one convex insulating layer overlaps with the at least one diffuse light emitting area on a lower surface of the pixel electrode. In one or more aspects, the pixel electrode may further include an inclined portion in the at least one of the plurality of sub-light emitting areas.

According to the one or more example embodiments described herein, a display device can be provided that includes a substrate; a planarization layer disposed on the substrate; pixel electrodes disposed in a pixel electrode layer on the planarization layer; an insulating layer disposed between the planarization layer and the pixel electrode layer, and comprising openings overlapping with pixel electrodes; and at least one convex insulating layers disposed between the planarization layer and pixel electrodes, located in an island shape in the openings, and having a convex shape.

In one or more embodiments, the pixel electrodes include a first pixel electrode, a second pixel electrode, and a third pixel electrode, and the at least one convex insulating layers (510) includes at least one first convex insulating layers disposed on the first pixel electrode, at least one second convex insulating layers disposed on the second pixel electrode, and at least one third convex insulating layers disposed on the second pixel electrode.

In one or more embodiments, a number of the at least one third convex insulating layers is greater than a number of the at least one first convex insulating layers, and is less than a number of the at least one second convex insulating layers.

In one or more embodiments, the first pixel electrode is red pixel electrode, the second pixel electrode is green pixel electrode, and the third pixel electrode is blue pixel electrode.

In one or more embodiments, the number of the at least one third convex insulating layers is six, the number of the at least one first convex insulating layers is three, and the number of the at least one second convex insulating layers is nine.

In one or more embodiments, the display device further comprises one or two or more dateline separated from the at least one convex insulating layers through the planarization layer, the one or two or more dateline overlaps with at least one of the at least one first convex insulating layers and the at least one second convex insulating layers, and no dateline overlaps with the at least one third convex insulating layers.

In one or more embodiments, the display device further comprises a source-drain electrode pattern disposed in the planarization layer and separated from the at least one convex insulating layers, the source-drain electrode pattern overlaps with at least one of the at least one first convex insulating layers, the at least one second convex insulating layers, and the at least one third convex insulating layers.

According to one or more example embodiments of the present disclosure, a display panel can be provided that includes a substrate including a flat area and a bending area, a planarization layer disposed on the substrate, a first pixel electrode located in the flat area and disposed in a pixel electrode layer on the planarization layer, a second pixel electrode located in the bending area and disposed in the pixel electrode layer on the planarization layer, an insulating layer disposed between the planarization layer and the pixel electrode layer, and including a first opening overlapping with a portion of the first pixel electrode and a second opening overlapping with a portion of the second pixel electrode, at least one first convex insulating layer disposed on the planarization layer, located in an island shape in the first opening, and having a convex shape, and at least one second convex insulating layer disposed on the planarization layer, located in an island shape in the second opening, and having a convex shape. In one or more aspects, the first pixel electrode may include a first curved surface disposed along an upper surface of the at least one first convex insulating layer in the first opening, and the second pixel electrode may include a second curved surface disposed along an upper surface of the at least one second convex insulating layer in the second opening. In one or more aspects, an area of a lower surface of the at least one second convex insulating layer may be greater than that of a lower surface of the at least one first convex insulating layer.

According to one or more example embodiments of the present disclosure, a display panel can be provided that includes a substrate on which a plurality of subpixels are disposed, a plurality of main light emitting areas overlapping with the plurality of subpixels, a plurality of sub-light emitting areas surrounding the plurality of main light emitting areas, wherein at least one diffuse light emitting area is included in each of the plurality of main light emitting areas. In one or more aspects, and the diffuse light emitting area may cause light emitted therefrom to have an emission angle that is not perpendicular to the substrate.

According to one or more example embodiments of the present disclosure, a display panel can be provided that includes a substrate; a planarization layer disposed on the substrate; pixel electrodes disposed in a pixel electrode layer on the planarization layer; an insulating layer disposed between the planarization layer and the pixel electrode layer, and comprising openings overlapping with pixel electrodes; and at least one convex insulating layers disposed between the planarization layer and pixel electrodes, located in an island shape in the openings, and having a convex shape.

Although the exemplary embodiments of the present disclosure have been disclosed hereinabove, it may be understood by those skilled in the art that the present disclosure may be variously modified and altered without departing from the scope and spirit of the present disclosure described in the following claims.

1. A display device comprising:
a substrate comprising a flat area and a bending area;
a planarization layer disposed on the substrate;
a first pixel electrode located in the flat area and disposed in a pixel electrode layer on the planarization layer;
a second pixel electrode located in the bending area and disposed in the pixel electrode layer on the planarization layer;
an insulating layer disposed between the planarization layer and the pixel electrode layer, the insulating layer comprising a first opening overlapping with a portion of the first pixel electrode and a second opening overlapping with a portion of the second pixel electrode;
at least one first convex insulating layer disposed on the planarization layer, located in an island shape in the first opening, and having a convex shape; and
at least one second convex insulating layer disposed on the planarization layer, located in an island shape in the second opening, and having a convex shape,
wherein the first pixel electrode comprises a first curved portion disposed along an upper surface of the at least one first convex insulating layer in the first opening, and the second pixel electrode comprises a second curved portion disposed along an upper surface of the at least one second convex insulating layer in the second opening, and
wherein an area of a lower surface of the at least one second convex insulating layer) is greater than an area of a lower surface of the at least one first convex insulating layer.

2. The display device of claim 1, wherein the first pixel electrode comprises a first inclined portion extending along a side surface of the insulating layer in the first opening, and
wherein the second pixel electrode comprises a second inclined portion extending along a side surface of the insulating layer in the second opening.

3. The display device of claim 2, further comprising:
a bank disposed on the first pixel electrode and the second pixel electrode, the bank comprising:
a first bank opening overlapping with the first inclined portion and the second inclined portion, the first bank opening located in the first opening; and
a second bank opening located in the second opening.

4. The display device of claim 1, wherein the at least one first convex insulating layer and the at least one second convex insulating layer comprise a same material as the planarization layer and wherein a height of the insulating layer is greater than heights of each of the at least one first convex insulating layer and the at least one second convex insulating layer.

5. The display device of claim 1, wherein a surface area of the upper surface of the at least one first convex insulating layer is less than a surface area of the upper surface of the at least one second convex insulating layer.

6. The display device of claim 1, wherein a height of the at least one first convex insulating layer is less than a height of the at least one second convex insulating layer.

7. The display device of claim 1, wherein the at least one first convex insulating layer overlaps with the first pixel electrode and the at least one second convex insulating layer overlaps with the second pixel electrode.

8. The display device of claim 1, further comprising:
a third pixel electrode disposed in the flat area; and
at least one third convex insulating layer overlapping with the third pixel electrode,
wherein a color of light emitted from an emission layer on the first pixel electrode and a color of light emitted from an emission layer on the third pixel electrode are different from each other, and
wherein a number of the at least one first convex insulating layer and a number of the at least one third convex insulating layer are different from each other.

9. The display device of claim 8, wherein the number of the at least one first convex insulating layer is greater than the number of the at least one third convex insulating layer.

10. The display device of claim 8, further comprising:
a fourth pixel electrode disposed in the bending area and spaced apart from the second pixel electrode; and
at least one fourth convex insulating layer overlapping with the fourth pixel electrode,
wherein a size of the at least one second convex insulating layer is different from a size of the at least one fourth convex insulating layer.

11. The display device of claim 10, wherein each of the at least one second convex insulating layer and the at least one fourth convex insulating layer has an oval shape, and
wherein a length of a major axis of the at least one second convex insulating layer is less that of a major axis of the at least one fourth convex insulating layer.

12. The display device of claim 8, wherein a total area of the at least one second convex insulating layer disposed in the bending area is greater than a total area of the at least one first convex insulating layer disposed in the flat area.

13. The display device of claim 1, further comprising:
an encapsulation layer disposed on the first pixel electrode and the second pixel electrode; and
a color filter layer disposed on the encapsulation layer,
wherein at least a portion of each of a plurality of color filters included in the color filter layer overlaps with the at least one first convex insulating layer or the at least one second convex insulating layer.

14. A display device comprising:
a substrate;
a planarization layer disposed on the substrate;
pixel electrodes disposed in a pixel electrode layer on the planarization layer;
an insulating layer disposed between the planarization layer and the pixel electrode layer, the insulating layer comprising openings overlapping with pixel electrodes; and
at least one convex insulating layer disposed between the planarization layer and pixel electrodes, located in an island shape in the openings, and having a convex shape.

15. The display device of claim 14, wherein the pixel electrodes include a first pixel electrode, a second pixel electrode, and a third pixel electrode, and
wherein the at least one convex insulating layer includes at least one first convex insulating layer disposed on the first pixel electrode, at least one second convex insulating layer disposed on the second pixel electrode, and at least one third convex insulating layer disposed on the second pixel electrode.

16. The display device of claim 15, wherein a number of the at least one third convex insulating layer is greater than a number of the at least one first convex insulating layer, and is less than a number of the at least one second convex insulating layer.

17. The display device of claim 16, wherein the first pixel electrode is red pixel electrode, the second pixel electrode is green pixel electrode, and the third pixel electrode is blue pixel electrode.

18. The display device of claim 16, wherein the number of the at least one third convex insulating layer is greater than the number of the at least one first convex insulating layer, and the number of the at least one second convex insulating layer is greater than the number of the at least one third convex insulating layer and the number of the at least one first convex insulating layer.

19. The display device of claim 17, further comprising:
at least one data line separated from the at least one convex insulating layer through the planarization layer,
wherein, the at least one data line overlaps with at least one of the at least one first convex insulating layer and the at least one second convex insulating layer, and no dateline overlaps with the at least one third convex insulating layer.

20. The display device of claim 17, further comprising:
a source-drain electrode pattern disposed in the planarization layer and separated from the at least one convex insulating layer,
wherein the source-drain electrode pattern overlaps with at least one of the at least one first convex insulating layer, the at least one second convex insulating layer, and the at least one third convex insulating layer.
